(19) United States
(12) Patent Application Publication
(10) Pub. No.: US 2008/0218026 A1
(43) Pub. Date: Sep. 11, 2008

(54) Piezoelectric package with enlarged conductive layers

(75) Inventors: Baruch Pletner, Newton, MA (US); Grace R. Kessenich, Somerville, MA (US)

Correspondence Address: Vista IP Law Group LLP, 2040 MAIN STREET, 9TH FLOOR, IRVINE, CA, 92614, US

(73) Assignee: IPTRADE, INC., Newton, MA (US)

(21) Appl. No.: 12/038,782

(22) Filed: Feb. 27, 2008

Related U.S. Application Data
(60) Provisional application No. 60/891,934, filed on Feb. 27, 2007.

(51) Int. Cl. H01L 41/053; H01L 41/083

(52) U.S. Cl. 310/314; 310/348; 310/344

(57) ABSTRACT

A piezoelectric package comprises a piezoelectric plate having a first planar surface and a second planar surface that are electrically isolated from each other. The piezoelectric package further comprises a first electrically conductive layer electrically coupled to the first planar surface, and a second electrically conductive layer electrically coupled to the second planar surface. The piezoelectric package further comprises a first electrically insulative material (e.g., a rigid fiber composite material) encapsulating the piezoelectric plate and at least portions of the first and second electrically conductive layers.

### RELATED APPLICATION

This application claims the benefit of U.S. Provisional Patent Application Ser. No. 60/891,934, filed Feb. 27, 2007. This application is filed concurrently with U.S. patent application Ser. No. 12/______ (VIP Docket No. IPT-006(2)), entitled “Piezoelectric Package with Improved Lead Structure” and U.S. patent application Ser. No. 12/______ (VIP Docket No. IPT-006(3)), entitled “Piezoelectric Package with Improved Lead Structure”, the disclosure of which are expressly incorporated herein by reference.

### FIELD OF THE INVENTION

The present inventions generally relate to devices for sensing and suppressing vibrations, and in particular, to piezoelectric sensors and actuators for use on equipment.

### BACKGROUND OF THE INVENTION

Structural vibration is one of the key performance limiting phenomena in many types of advanced machinery, such as space launch vehicle shrouds, all types of jet and turbine engines, robots, and many types of manufacturing equipment. Because structural vibration depends on many factors that are not easily modeled, such as boundary and continuity conditions, as well as the disturbance environment, it is impossible to design a machine from the first prototype that will meet all vibration requirements. This means that the final steps in analyzing and suppressing vibration are accomplished after the actual production unit has been completed.

To address this shortfall, it is known to incorporate vibration analysis and suppression systems into equipment. In general, a typical vibration analysis and suppression system includes a multitude of vibration sensors and vibration actuators that are installed on-board the equipment in selected locations. The system also includes a control system that transmits control signals in accordance with a vibration suppression algorithm to the actuators during normal operation of the equipment to mechanically suppress the vibrations. Using a feedback loop, the sensed vibration information is fed back to the control circuitry, which adjusts the control signals in response to dynamic conditions.

It is also known to incorporate vibration analysis devices into equipment for the purpose of performing non-destructive testing (i.e., testing that does not destroy the equipment). For example, sensors can be incorporated into aircraft to measure flow and combustion induced vibrations in turbines or combustion housings of propulsion systems, can be incorporated pre-forms, concrete and other structures that require cure-monitoring, or can be incorporated into equipment to monitor damage (e.g., delamination) that may present as a change in vibration characteristics.

Significant to the present invention, piezoelectric sensors and actuators are utilized extensively to detect and/or suppress vibrations in equipment. Such piezoelectric devices can be incorporated into the host structure of the equipment as plates that can be embedded within the host structure or externally applied to the host structure as patches. When used as a sensor, a piezoelectric plate contracts and expands along a plane parallel to the surface of the plate (in the x- and y-direction) in response to vibrations induced within the piezoelectric plate via the host structure, which in turn, induces an electrical field in a plane perpendicular to the surface of the plate (in the z-direction), creating a voltage potential between the top and bottom surfaces of the piezoelectric plate. In a similar manner, when used as an actuator, a piezoelectric plate contracts and expands along a plane parallel to the surface of the plate (in the x- and y-direction) in response to a voltage potential between the top and bottom surfaces of the piezoelectric plate that induces an electrical field induced in a plane perpendicular to the surface of the plate (in the z-direction), which in turn, induces a vibration in the host structure. Whether used as a sensor or an actuator, the magnitude of the voltage potential on the top and bottom surfaces of the piezoelectric plate will be proportional to the magnitude of the contraction/expansion of the piezoelectric plate, and thus, the vibrations of the host structure. Thus, the nature of the vibrations sensed within the host structure can be determined via analysis of the voltage potential, and the nature of the vibrations induced within the host structure can be controlled via the voltage potential applied to the piezoelectric plate.

To protect the very fragile piezoelectric plate from damage, and to functionally couple the piezoelectric plate between the host structure and the external circuitry that senses vibrations from the host structure and/or induces vibrations within the host structure, it is necessary to incorporate the piezoelectric plate into a package. Such packages typically include a pair of wire leads respectively coupled to the top and bottom surfaces of the piezoelectric plate to convey the voltage potential to and/or from the piezoelectric plate, and one or more layers of an electrically insulating material that encapsulate the piezoelectric plate to not only protect it from damage that might otherwise occur when dropped or mishandled, but also to electrically insulate the piezoelectric plate and wire leads from the host structure.

Typically, the piezoelectric plate, wire leads, and insulating material are incorporated together as a bonded laminate or cured composite structure, which may sometimes be placed within a rigid frame. However packaged, it is important that the mechanical coupling efficiency between the piezoelectric plate and the host structure be as high as possible, so that vibration between the piezoelectric plate and host structure is efficiently transferred. To this end, the material in which the piezoelectric plate is encapsulated and the manner of encapsulating the piezoelectric plate must be judiciously selected.

In addition to ensuring that vibration is efficiently coupled between the piezoelectric plate and the host structure, it is important to ensure that the wire leads are efficiently coupled to piezoelectric plate both during its manufacture and during the useful life of the host structure. In typical piezoelectric packages, the wire leads are connected to a relatively small region of the piezoelectric plate via an electrically conductive material that is sputtered or otherwise deposited onto the opposing planar surfaces of the piezoelectric plate to form surface electrodes that uniformly distribute the electrical field applied or induced across the plate surfaces. As long as the piezoelectric plate remains undamaged, connection of the wire leads in this manner is sufficient.

If the piezoelectric plate along with the associated surface electrodes cracks, however, only the portion of the piezoelectric plate that is in contact with both of the wire leads will be functional. Because the wire leads will contact only a small region of the surface electrode on the piezoelectric plate, it is possible that less than ten percent of the piezoelectric plate will be active if damage occurs. Such degradation may occur even in the presence of microscopic or hairline fractures within the surface electrodes.

Significantly, because a wire lead creates highly localized pressure on the surface of a piezoelectric plate to which it is connected during curing of the piezoelectric package, the lead, itself, may actually create microcracks within the piezoelectric plate, thereby electrically isolating the most of the piezoelectric plate from the lead. In addition to damage to the piezoelectric plate, damage to the electrical lead, itself, may also occur due to any one of a variety of reasons; for example, delamination of the package, localized micro-cracking, and in military applications, bullet holes and shrapnel. As a result, a single broken wire lead may render the entire piezoelectric package useless.

Once a piezoelectric package, which may include multiple piezoelectric plates, is damaged, either because a piezoelectric plate no longer actively functions or because a single lead has been broken, there is nothing to do to correct the problem, and thus, the entire package must be scrapped. Typical piezoelectric packages are relatively expensive, and therefore, total replacement of a package, is not economical. With respect to non-destructive testing in mission critical components, such as those found in military applications, if the piezoelectric package fails to function, delamination will not be detected, potentially leading to severe consequences, including loss of life. Particularly in military environments where structural components are worked to the limit in field conditions, a single broken lead can terminate the mission.

Besides reliability issues, the use of wire leads poses manufacturing issues. For example, a pair of lead wires typically must be connected to each piezoelectric plate within a package. A typical piezoelectric package may include three-by-three array of piezoelectric plates, thereby requiring eighteen wire leads. Thus, in a typical piezoelectric package, many electrical connections must be formed before the package is cured, making the fabrication process both labor intensive and mistake prone; that is, one missed connection will render the piezoelectric package useless. Any missed connection will typically be discovered only after the piezoelectric package has been cured, in which case, the entire piezoelectric package must be scrapped.

The use of wire leads may also pose implementation and integration issues. For example, due to their one-dimensional nature, there is only one location on the piezoelectric package where a single wire emerges and electrical contact can be made. Thus, if the electronics are located on a different side of the piezoelectric package from which the wire lead emerges, the wire lead (or a lead extension) must be routed from the side of the piezoelectric package from which the wire lead emerges to this different side. Alternatively, the piezoelectric package can be specifically designed to place the side of the piezoelectric package from which the wire lead emerges on the side of the electronics. However, this does not easily allow for multiple uses of the same piezoelectric package and interchangeability. In addition, because a typical piezoelectric package includes many piezoelectric plates, some of which may serve as sensing devices and others of which may serve as actuating devices, it may be difficult to determine which ones of the many lead wires emerging from the piezoelectric package are connected to sensing devices, and which ones are connected to actuators in order to allow proper connection to the external electronics.

Thus, there remains a need for an improved method of manufacturing a piezoelectric package for use as a vibration sensor and/or vibration actuator on the host structure of equipment.

### SUMMARY OF THE INVENTION

In accordance with the present invention, a piezoelectric package is provided. The piezoelectric package may be incorporated into a system. In particular, the system may comprise equipment susceptible to vibration, the piezoelectric package mounted on the equipment, and electronic circuitry configured for sensing and/or actuating vibrations within the equipment via the piezoelectric package.

The piezoelectric package comprises a piezoelectric plate having a first planar surface and a second planar surface that are electrically isolated from each other. The piezoelectric package further comprises a first electrically conductive layer electrically coupled to the first planar surface, and a second electrically conductive layer electrically coupled to the second planar surface. The piezoelectric package further comprises a first electrically insulative material (e.g., a rigid fiber composite material) encapsulating the piezoelectric plate and at least portions of the first and second electrically conductive layers. The ratio of the area of the first electrically conductive layer to the area of the first planar surface is equal to or greater than unity. The ratio of the area of the second electrically conductive layer to the area of the second planar surface may also be equal to or greater than unity. Although the present inventions should not be so limited in their broadest aspects, the relative large area of the first and/or second electrically conductive layers provides a more reliable electrical connection to the first and/or second planar surfaces of each piezoelectric plate even in the presence of damage to the electrically conductive layers and/or each piezoelectric plate.

### BRIEF DESCRIPTION OF THE DRAWINGS

The drawings illustrate the design and utility of preferred embodiments of the present invention, in which similar elements are referred to by common reference numerals. In order to better appreciate how the above-recited and other advantages and objects of the present inventions are obtained, a more particular description of the present inventions briefly described above will be rendered by reference to specific embodiments thereof, which are illustrated in the accompanying drawings. Understanding that these drawings depict only typical embodiments of the invention and are not therefore to be considered limiting of its scope, the invention will be described and explained with additional specificity and detail through the use of the accompanying drawings in which:

FIG. 1 is a plan view of a vibration analysis and suppression system constructed in accordance with one preferred embodiment of the present inventions;

FIG. 2 is a perspective view of one embodiment of a piezoelectric package that can be used as a vibration sensing device or vibration actuating device within the system of FIG. 1;

FIG. 3 a cross-sectional view of the piezoelectric package, taken along the line 3-3;

FIG. 4 is an exploded view of a laminate structure that can be cured to form the piezoelectric package of FIG. 2;

FIG. 5a-5j are perspective views illustrating a method of manufacturing the piezoelectric package of FIG. 2;

FIG. 6 is a perspective view of another embodiment of a piezoelectric package that can be used as a vibration sensing device and/or vibration actuating device within the system of FIG. 1;

FIG. 7 is a perspective view of still another embodiment of a piezoelectric package that can be used as a vibration sensing device and/or vibration actuating device within the system of FIG. 1

FIG. 8 is a perspective view of another embodiment of a piezoelectric package that can be used as a vibration sensing device or vibration actuating device within the system of FIG. 1;

FIG. 9 is a side view of the piezoelectric package of FIG. 8;

FIG. 10 is a perspective view of a connector assembly that can be incorporated into the piezoelectric package of FIG. 8;

FIG. 11 is a perspective view of the composite structure of the piezoelectric package of FIG. 8;

FIG. 12 is a cross-sectional view of the composite structure of FIG. 11, taken along the line 12-12;

FIG. 13 is an exploded view of a laminate structure that can be cured to form the composite structure of FIG. 11;

FIGS. 14a-14s are perspective views illustrating a method of manufacturing the composite structure of FIG. 11;

FIG. 15 is a plan view of the composite structure of still another embodiment of a piezoelectric package that can be used as a vibration sensing device or vibration actuating device within the system of FIG. 1;

FIG. 16 is a cross-sectional view of the composite structure of FIG. 15, taken along the line 16-16;

FIG. 17 is an exploded view of a laminate structure that can be cured to form the composite structure of FIG. 15;

FIG. 18 is a top view of a first layer of the laminate structure of FIG. 17;

FIG. 19 is a top view of a second layer of the laminate structure of FIG. 17;

FIG. 20 is a top view of a third layer of the laminate structure of FIG. 17;

FIG. 21 is a top view of a fourth layer of the laminate structure of FIG. 17;

FIG. 22 is a perspective view of an environmental case in which a piezoelectric package can be disposed;

FIG. 23 is a perspective view of a base plate of the environmental case of FIG. 22;

FIG. 24 is a perspective top view of a cover of the environmental case of FIG. 22;

FIG. 25 is a perspective bottom view of the cover of FIG. 24;

FIG. 26 is a perspective view of an alternative base plate that can be used with the cover of FIGS. 24 and 25;

FIG. 27 is a perspective view of an environmental case that can be created using the cover of FIGS. 24 and 25 and the alternative base plate of FIG. 26;

FIG. 28 is a perspective view of a sub-assembly created by mounting the piezoelectric package of FIG. 8 to the base plate of FIG. 23;

FIG. 29 is a perspective view of a sub-assembly created by mounting the rubber pad to the piezoelectric package of FIG. 28;

FIG. 30 is a perspective view of a sub-assembly created by mounting the rubber pad mounted to the cover of FIG. 25; and

FIG. 31 is a perspective view of protected piezoelectric package created by mounting the sub-assembly of FIG. 30 to the sub-assembly of FIG. 29.

### DETAILED DESCRIPTION OF THE EMBODIMENTS

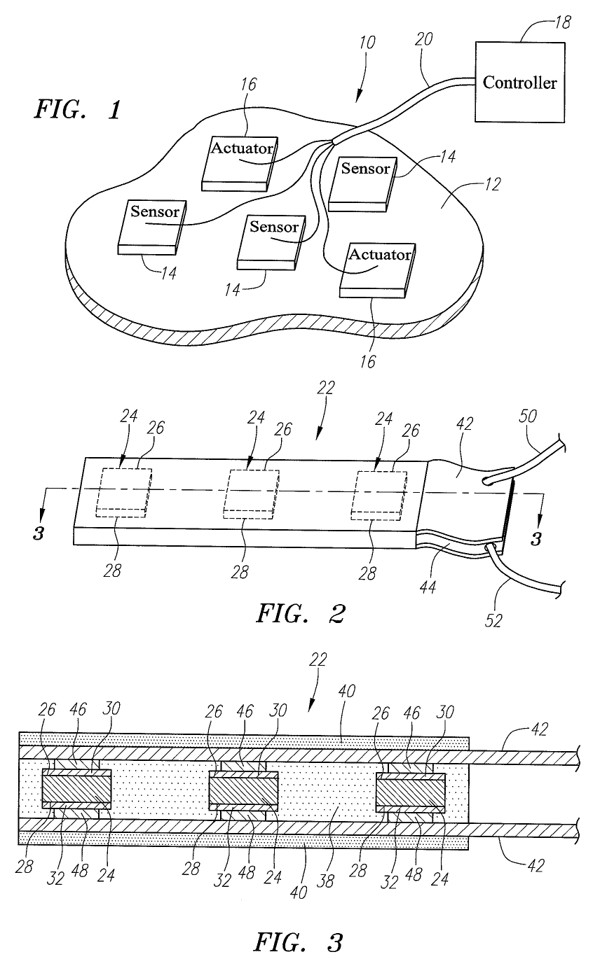

Referring to FIG. 1, a vibration analysis and suppression system 10 constructed in accordance with one embodiment of the present inventions is described. The system 10 is designed to sense and suppress vibrations within the host structure 12 of equipment whose performance is highly sensitive to vibration. To this end, the system 10 generally comprises a plurality of vibration sensing devices 14, a plurality of vibration actuating devices 16, and a controller 18 coupled to the vibration sensing devices 14 and vibration actuating devices 16 via cables 20. The vibration sensing devices 14 sense environmental vibrations within the host structure 12 and feed vibration response information back to the controller 18, which generates and transmits vibration control signals to the vibration actuating devices 16, which then respond by inducing vibrations within the host structure 12 to suppress the environmental vibrations. The vibration sensing devices 14 and vibration actuating devices 16 are both shown as being mounted to the exterior surface of the host structure 12, e.g., using a quick setting adhesive, such as epoxy, although in alternative embodiments, these devices can be embedded within the host structure 12.

While separate and dedicated vibration sensing devices 14 and vibration actuating devices 16 are shown, the functionality of these devices can be combined into a single vibration sensing/actuating device. In the illustrated embodiment, the controller 18 is remote from the host structure 12, although in alternative embodiments, the controller 18 can be located on the host structure 12 or anywhere else on the equipment. In other embodiments, the circuitry of the controller 18 is collocated with one of, or distributed amongst, the vibration sensing devices 14 and vibration actuating devices 16, similar to the manner disclosed in U.S. patent application Ser. No. 11/262,083, which is expressly incorporated herein by reference. It should be appreciated that the system 10 can alternatively be used to perform non-destructive testing of the host structure 12, in which case, vibration actuating devices 16 may not be utilized.

Referring to FIGS. 2 and 3, each of the vibration sensing devices 14 and vibration actuating devices 16 takes the form of a piezoelectric package 22, the use of which will characterize the device as either a vibration sensing device 14 and/or a vibration actuating device 16. That is, the piezoelectric package 22 can be characterized as a vibration sensing device 14 if vibration sensing signals are transmitted from the piezoelectric package 22 to the controller 18, and can be characterized as a vibration actuating device 16 if vibration control signals are transmitted from the controller 18 to the piezoelectric package 22. In the illustrated embodiment, the piezoelectric package 22 takes the form of a stiff, low-profile card that can be bonded to the exterior surface of, or embedded within, the host structure 10 without substantially changing the structural or physical response characteristics of the host structure 10. For the purposes of this specification, an element is stiff if it exhibits a Young's modulus greater than 1×10⁵.

Referring specifically to FIG. 3, which exaggerates the thickness of the layers of the piezoelectric package 22 for purposes of illustration, the piezoelectric package 22 comprises a number of piezoelectric plates 24 (shown in phantom in FIG. 2), each having opposing planar top and bottom surfaces 26, 28. In the illustrated embodiment, three piezoelectric plates 24 are provided, although the piezoelectric package 22 may include more or less piezoelectric plates 24, including a single piezoelectric plate. Also, although the piezoelectric plates 24 are illustrated in a single layer, the piezoelectric plates 24 can be arranged in multiple layers, as will be discussed in further detail below with respect to another embodiment. Although the piezoelectric plates 24 are illustrated in a single column or row for purposes of simplicity, alternative piezoelectric packages 22 may include a two-dimensional array of piezoelectric plates 24 (e.g., a three-by-three array). The piezoelectric package 22 further comprises a pair of surface electrodes 30, 32 respectively disposed on the planar surfaces 26, 28 of each piezoelectric plate 24. Such surface electrodes 30, 32 can be formed on the planar surfaces 26, 28 using any suitable process, e.g., electroplating or sputtering. The piezoelectric plate 24 can be composed of any suitable piezoelectric material, such as, e.g., lead zirconate titanate (PZT), and the surface electrodes 30, 32 can be composed of any suitable electrically conductive material, such as nickel.

Each piezoelectric plate 24 has a relatively small thickness; for example, between 5-100 mils thick. In the illustrated embodiment, the thickness of the piezoelectric plates 24 is 60 mils. Notably, for purposes of sensing, thicker piezoelectric plates 24 function better. Such a relatively small thickness allows high electrical field strengths to be achieved when a small amount of voltage (e.g., 10-50V) is applied or induced between the planar surfaces 26, 28, and advantageously reduces the profile of the piezoelectric package 22. Due to this small thickness, however, each piezoelectric plate 24 is fragile and may break due to irregular stresses when handled, assembled, or cured. To this end, the piezoelectric plates 24 are encapsulated within a rigid electrically insulative material. The piezoelectric package 22 is also designed, such that it continues to function even if piezoelectric plates 24 are fractured or otherwise damaged.

To this end, the piezoelectric package 22 comprises a pair of electrically conductive layers 34, 36 respectively disposed relative to the planar surfaces 26, 28 of each piezoelectric plate 24. As will be discussed in further detail below, the conductive layers 34, 36 are electrically coupled to the respective planar surfaces 26, 28 of the piezoelectric plate 24 via the surface electrodes 30, 32. In the illustrated embodiment, the conductive layers 34, 36 are composed of a suitable electrically conductive material, such as nickel, which has a relatively high electrical conductivity, does not outgas during curing of the piezoelectric package 22, and does not easily corrode. The conductive layers 34, 36 are also composed of a porous material to facilitate integration with adjacent electrically insulative material, as will be described in further detail below. In the illustrated embodiment, the porous material takes the form of a mesh, although other types of porous material, such as braid or weave, can be used for the conductive layers 34, 36.

Notably, the conductive layers 34, 36 are continuous and span the planar surfaces 26, 28 of the piezoelectric plate 24 in both the x- and y-directions. In the illustrated embodiment, the area of the conductive layer 34 is large relative to the combined areas of the planar surfaces 26 of the piezoelectric plates 24, and the area of the conductive layer 36 is large relative to the combined areas of the planar surfaces 28 of the piezoelectric plates 24. In particular, the ratio of the area of the conductive layer 34 over the total area of the first planar surfaces 26 is equal to or greater than unity, and the ratio of the area of the conductive layer 36 over the total area of the second planar surfaces 28 is equal to or greater than unity. Because an increased surface for electrically coupling the planar surfaces 26, 28 of the piezoelectric plates 24 is provided, the piezoelectric package 22 may still function even if the portions of the conductive layers 34, 36 and piezoelectric plates 24 are damaged. That is, the large area conductive layers 34, 36 would have to be completely severed for the piezoelectric package 22 to cease functioning properly.

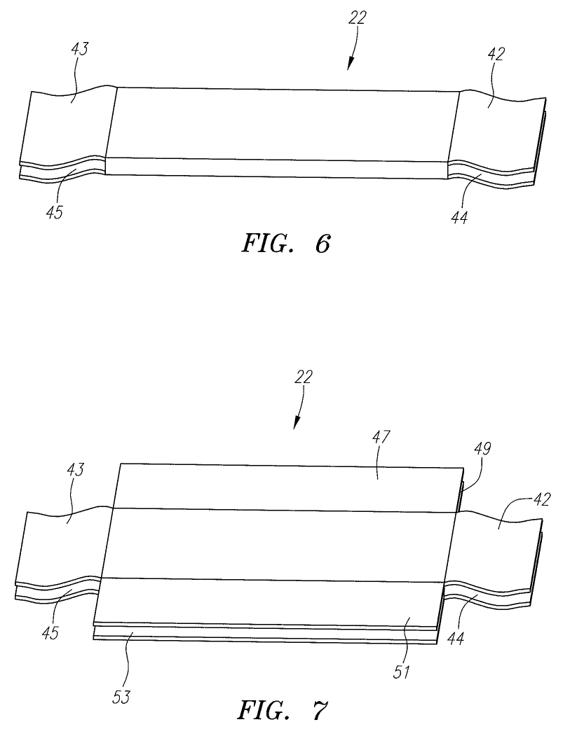

Exposed portions 42, 44 of the conductive layers 34, 36 emerge from the piezoelectric package 22 for connection to electrical leads, as will be discussed in further detail below. In the embodiment illustrated in FIG. 2, the exposed portions 42, 44 of the conductive layers 34, 36 only emerge from one side of the piezoelectric package 22. In alternative embodiments, exposed portions of the conductive layers 34, 36 may emerge from multiple sides of the piezoelectric package. For example, as illustrated in FIG. 6, additional exposed portions 43, 45 of the conductive layers 34, 36 emerge from the piezoelectric package 22 on a side opposite from the side from which the exposed portions 42, 44 emerge from. As illustrated in FIG. 7, additional exposed portions 47, 49, 51, 53 of the conductive layers 34, 36 emerge from the remaining two sides of the piezoelectric package 22. In this case, exposed portions of the conductive layers emerge from all sides of the piezoelectric package 22. It can be appreciated that, due to the two-dimensionality of the conductive layers 34, 36, many more connection possibilities can be achieved by exposing portions of the conductive layers 34, 36 on several sides of the piezoelectric package 22, thereby providing a more flexible implementation or integration of the piezoelectric package 22, as well as making the use of the piezoelectric package 22 more ubiquitous.

As shown in FIG. 3, the piezoelectric package 22 further comprises an inner structural material 38 located between the conductive layers 34, 36, thereby ensuring that the conductive layers 34, 36 are electrically isolated from each other, and further ensuring that the piezoelectric plates 24 are electrically isolated from the environment (e.g., from the host structure 12), thereby preventing electrical shorting. The inner structural material 38 also homogenizes the pressure on the piezoelectric plates 24, thereby making microcracks much less likely to form in the piezoelectric plates 24. The piezoelectric package 22 further comprises an outer structural material 40 that encapsulates the conductive layers 34, 36 (with the exception of end portions 42, 44), along with the piezoelectric plates 24, thereby ensuring that the conductive layers 34, 36 are electrically isolated from the environment (e.g., from the host structure 12), thereby preventing electrical shorting.

In the illustrated embodiment, the inner and outer structural materials 38, 40 are composed of a rigid composite fiber material, thereby protecting the piezoelectric plates 24 from mishandling and providing ideal mechanical coupling between the piezoelectric plates 24 and the host structure 12 on or in which the piezoelectric package 22 is mounted. In addition, the rigid composite fiber material is easy to handle risking damage to the piezoelectric package 22. In the illustrated embodiment, the inner and outer structural materials 38, 40 are composed of an electrically insulative composite fiber material, such as a fiber glass/epoxy material, although other materials can be used as long as they are electrically insulative and have a bonding material. Significantly, the bonding material of the inner and outer structural materials 38, 40 are embedded within the mesh of the conductive layers 34, 36 to maximize the mechanical integrity of the piezoelectric package 22 and to minimize the risk of delamination. In some cases, portions of the inner structural material 38 may be composed of an electrically conductive material, as long as such material does electrically couple to the piezoelectric plates 24 or conductive layers 34, 36. As a general rule, the thicker the inner and outer structural material 38, 40, the higher the Young's modulus is preferred to ensure that ideal mechanical coupling is achieved.

The piezoelectric package 22 further comprises vertical electrical conductors 46 extending through the inner structural material 38 between the conductive layer 34 and the respective surface electrodes 30 disposed on the piezoelectric plates 24, and vertical electrical conductors 46, 48 extending through the inner structural material 38 between the conductive layer 36 and the respective surface electrodes 32 disposed on the piezoelectric plates 24. Notably, the cross-sectional areas of the vertical electrical conductors 46, 48 are respectively less than the areas of the first and second planar surfaces 26, 28 of the piezoelectric plates 24, so that the inner structural material 38 is disposed on the outer peripheral regions of the surface electrodes 30, 32. In this manner, electrical isolation between the conductive layers 34, 36 at the edges of the piezoelectric plates 24 is ensured.

As shown in FIG. 2 the piezoelectric package 22 further comprises first and second electrical leads 50, 52 respectively connected to the exposed portions 42, 44 of the conductive layers 34, 36 using suitable means, such as soldering or welding. Thus, the electrical lead 50 is electrically coupled to the first planar surfaces 26 of the piezoelectric plates 24 via the conductive layer 34, vertical conductors 46, and surface electrodes 30, and the electrical lead 52 is electrically coupled to the second planar surfaces 28 of the piezoelectric plates 24 via the conductive layer 36, vertical conductors 48, and surface electrodes 32. Instead of connecting leads directly to the exposed portions 42, 44 of the conductive layers 34, 36, piezoelectric package 22 may alternatively include a cable connector (not shown) coupled to the exposed portions 42, 44 of the conductive layers 34, 36. Such a connector will be described in further detail below with respect to different embodiments of a piezoelectric package.

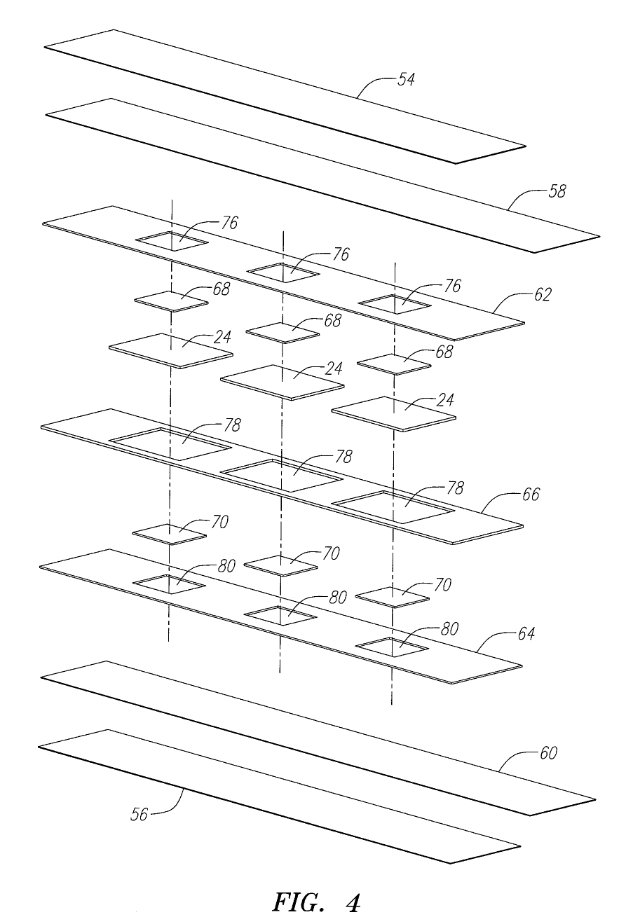

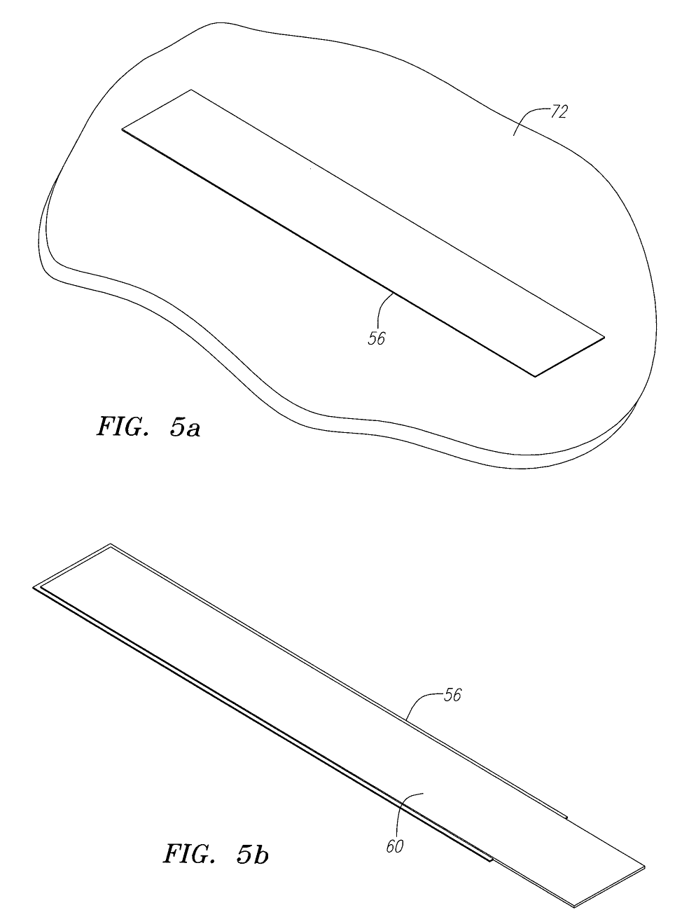

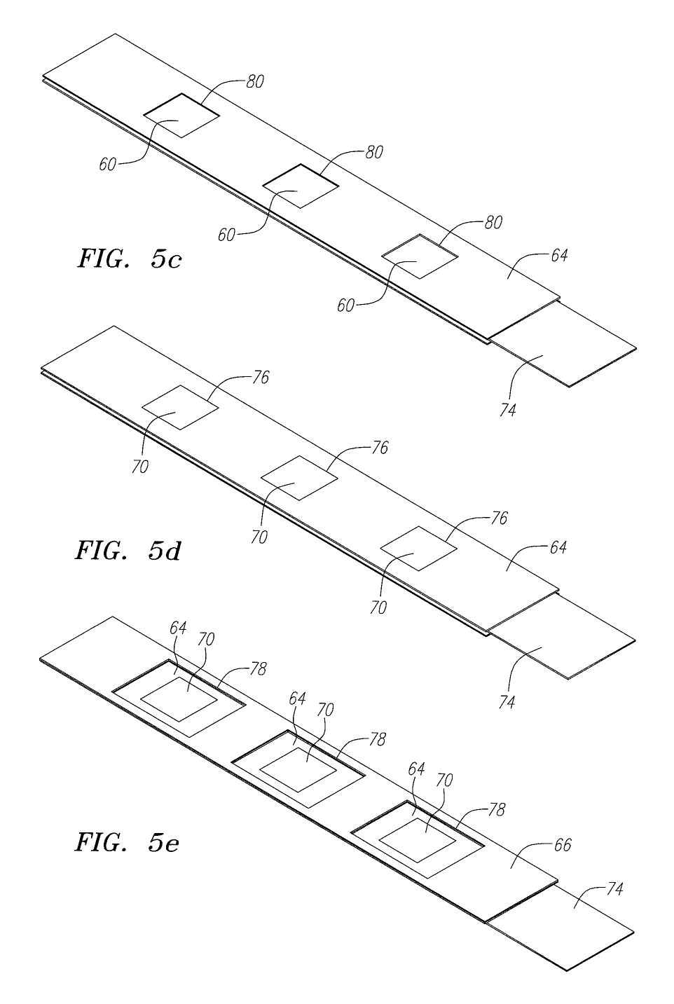

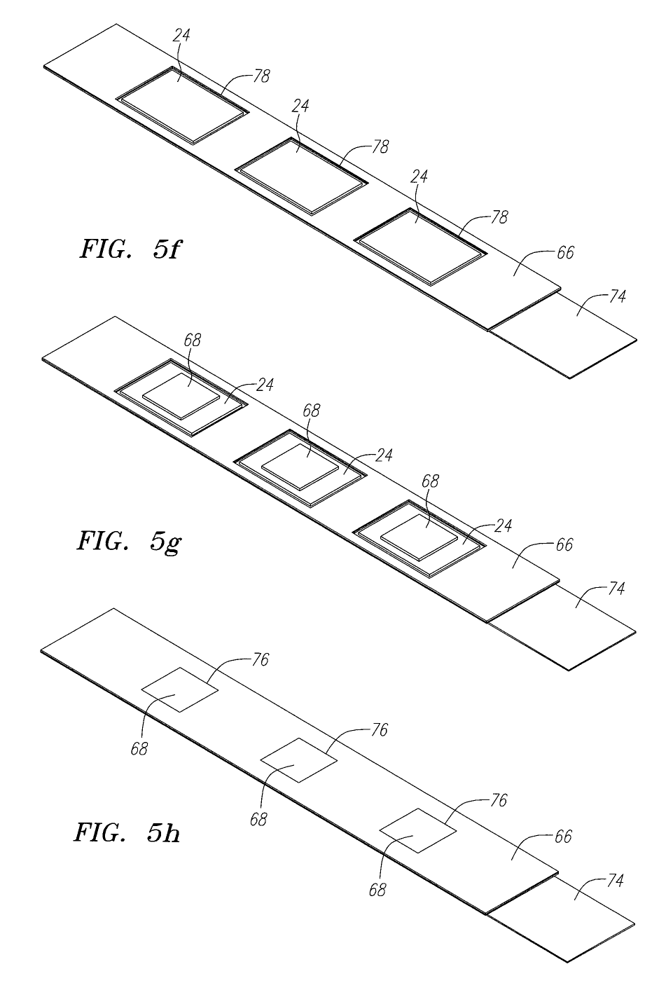

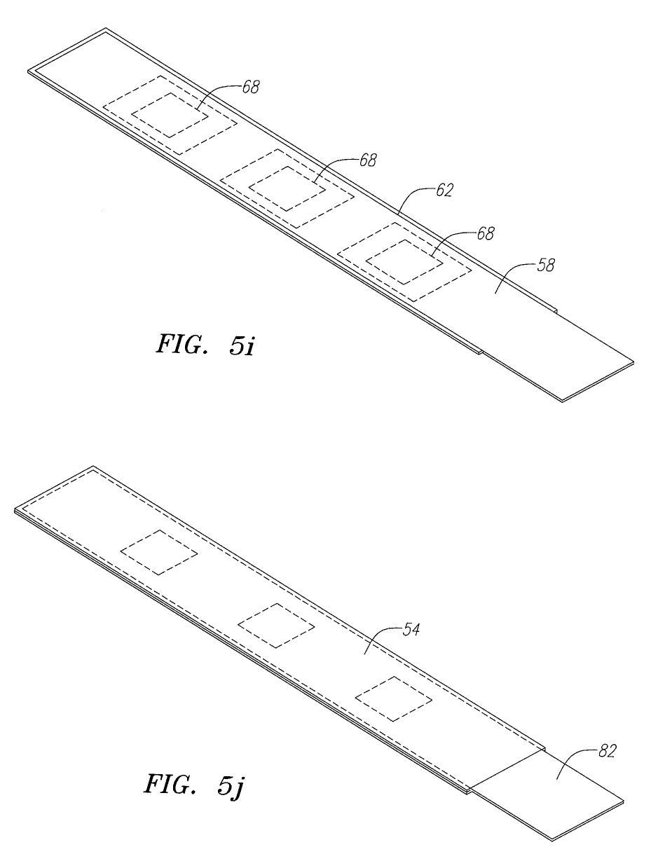

Having described its structure, a method of manufacturing the piezoelectric package 22 will be described with respect to FIG. 4 and FIGS. 5a-5j. In this method, the piezoelectric package 22 is created from a multilayer laminate comprising a layup of the three piezoelectric plates 24, two outer electrically insulative sheets 54, 56, two electrically conductive sheets 58, 60, two inner electrically insulative sheets 62, 64, a thickening sheet 66, and two sets of three small electrically conductive sheets 68, 70. Each of the foregoing sheets can be originally provided in a roll that is then cut to size. As will be described in further detail below, this layup is then cured to form a composite structure of the piezoelectric package 22. Notably, in the case where the piezoelectric plates 24 are divided into electrically isolated groups, each of the conductive sheets 68, 70 will be replaced with multiple conductive sheets.

Each of the insulative sheets 54, 56, 62, 64 and the thickening sheet 66 is composed of an electrically insulative fiber matrix impregnated with a resin, and in the illustrated method, a fiberglass/epoxy pre-impregnated material (e.g., E-761 Epoxy Pre-Preg with 7781 E-Glass), which has proven to be a good electrically insulating material with high strength. Alternatively, other pre-impregnated material compatible to composite manufacturing techniques can be used. Preferably, such alternative pre-impregnated material has a Young's modulus similar or greater than fiberglass/epoxy pre-impregnated material; for example, Kevlar®/epoxy pre-impregnated material. In an alternative embodiment, the thickening sheet 66 can be replaced with a composite material that is not necessarily electrically insulative, as long as the material does not contact the surface electrodes 30, 32 on the piezoelectric plates 24 or the piezoelectric plates 24 themselves. For example, the thickening sheet 66 may be composed of multiple layers of carbon or boron/epoxy pre-impregnated material, which advantageously has a higher Young's modulus than does fiberglass/epoxy pre-impregnated material.

The conductive sheets 58, 60, 68, 70 are composed of a suitably electrically conductive material that does not exhibit significant outgassing and does not easily corrode. In the illustrated method, the electrically conductive sheets 58, 60, 68, 70 are composed of nickel. The electrically conductive sheets 58, 60 are preferably composed of a porous material, such as a mesh, or alternatively, a braid or weave, to provide a more durable and integral mechanical connection to the adjacent insulative layers. In the illustrated embodiment, the conductive sheets 58, 60 are composed of a nickel mesh, e.g., Delker 4 Al 5-050. The conductive sheets 68, 70, which are not intended to come in contact with the insulative layers, can be composed of a solid and continuous material, although they can be composed of a porous material; for example, a nylon cloth impregnated with nickel material.

The insulative sheets 54, 56, 62, 64 can have any suitable thickness; for example, in the range of 5-20 mils when cured. In the illustrated embodiment, the insulative sheets 54, 56, 62, 64 each have a 9 mil thickness when cured. The conductive sheets 58, 60, 68, 70 can have any suitable thickness; for example, in the range of 1-10 mils. In the illustrated embodiment, the thickness of each of the conductive sheets 58, 60, 68, 70 is 4 mils. The thickening sheet 66, which will be located on the same plane as the piezoelectric plates 24, preferably has the same thickness as the combined thickness of the piezoelectric plates 24 and surface electrodes 30, 32.

The method of manufacturing the piezoelectric package 22 is first initiated by placing the insulative sheet 56 onto a movable, flat, supporting sheet 72 that can be placed into and removed from a curing oven (FIG. 5a). Next, the conductive sheet 60 is disposed over the insulative sheet 56 (FIG. 5b). In the illustrated method, the size of the conductive sheet 60 is smaller than the size of the insulative sheet 56 in one dimension. In particular, the top and bottom edges of the conductive sheet 60 do not reach the top and bottom edges of the insulative sheet 56. The size of the conductive sheet 60 is larger than the size of the insulative sheet 56 in the other dimension to provide an exposed portion 74 (FIG. 5c) on one side of the laminate to which the electrical lead 52 (shown in FIG. 2) is to be connected. The size of the conductive sheet 58 is similarly dimensioned with respect to the size of the insulative sheet 54 (FIG. 5j).

In this manner, electrical isolation between the conductive sheets 60, 58 themselves, as well as between the conductive sheets 60, 58 and the environment in which the piezoelectric package 22 is placed, is maximized. Significantly, if the conductive sheets 60, 58 are slightly misaligned during assembly, the smaller dimensions of the conductive sheets 60, 58 with respect to the insulative layers 56, 54 will prevent the edges of the conductive sheets 60, 58 from contacting each other. Alternatively, another exposed portion (not shown) of the conductive sheet 60 can be provided on the opposite side of the laminate to which the electrical lead 52 can be connected if the piezoelectric package 22 illustrated in FIG. 6 is desired. Or, the size of the conductive sheet 60 can be made larger than the size of the insulative sheet 56 in both dimensions, so that the exposed portions (not shown) of the conductive sheet 60 are provided on the remaining two sides of the laminate. Thus, it can be appreciated that connection to the piezoelectric package can be selectively provided on any of its sides simply by selecting the dimensions of the conductive sheet 60 relative to the dimensions of the insulative sheet 56.

Notably, if the piezoelectric plates 24 have multiple purposes (e.g., sensing versus actuating), the conductive sheet 60 can be replaced with multiple conductive sheets (e.g., two), with each conductive sheet 60 electrically coupled to the respective group of piezoelectric plates 24. In this case, the exposed portions of the multiple conductive sheets can emerge from different sides of the laminate (e.g., the exposed portion of the conductive sheet coupled to sensing piezoelectric plates can emerge on one side of the piezoelectric package 22, whereas the exposed portion of the conductive sheet coupled to actuating piezoelectric plates can emerge from a different side of the piezoelectric package 22), so that implementation and integration of the resulting piezoelectric package 22 is more easily accomplished.

Next, the insulative sheet 64 is disposed over the conductive sheet 60 (FIG. 5c). As shown, three cutout windows 80 are formed through the insulative sheet 64 corresponding to the centers of the piezoelectric plates 24. The size of the windows 80 are respectively smaller than the piezoelectric plates 24 to prevent the underlying conductive sheet 60 from conducting electricity to nothing other than the centers of the piezoelectric plates 24. That is, if the size of the windows 80 were equal to the size of the piezoelectric plates 24, it is possible that the underlying conductive sheet 60 may come in contact with the conductive sheet 58 (described below) at the periphery (i.e., edges) of any of the piezoelectric plates 24 during the curing process.

Thus, instead of disposing the piezoelectric plates 24 within the windows 80, the small conductive sheets 70 are respectively disposed within the windows 80 of the insulative sheet 64 in contact with the underlying conductive sheet 60, such that the small conductive sheets 70 are in the same plane as the insulative sheet 64 (FIG. 5d). The windows 80 respectively have the same size as the small conductive sheets 70 to minimize any discontinuities between the small conductive sheets 70 and the insulative sheet 64; that is, a smooth continuous surface is provided along the plane of the insulative sheet 64 and small conductive sheets 70. Sizing the windows 80 in this manner also facilitates alignment of the small conductive sheets 70 with the centers of the respective piezoelectric plates 24. As will be described in further detail below, these conductive sheets 70 will be placed into intimate electrical contact with the surface electrodes 32 located on the second planar surfaces 28 of the piezoelectric plates 24.

Next, the thickening sheet 66 is disposed over the insulative sheet 64 (FIG. 5e). As shown, three windows 78 are formed through the insulative sheet 66, each of which has the same size as the corresponding piezoelectric plate 24. The piezoelectric plates 24 are respectively disposed within the windows 78 of the insulative sheet 66 in contact with the respective small conductive sheets 70 (FIG. 5f). Notably, the polarities of the piezoelectric plates 24 are all oriented in the same direction when disposed within the windows 78. Thus, the surface electrodes 32 (shown in FIG. 3) of the piezoelectric plates 24 will be in electrical contact with the underlying conductive sheet 60 via the respective small conductive sheets 70. As can be appreciated, connection between the piezoelectric plates 24 and the conductive sheet 60 is easily accomplished as part of the process of disposing the different layers of the structure over one another, thereby avoiding the need to separately make connections to the piezoelectric plates 24.

In an alternative embodiment, the small conductive sheets 70 are not used, in which case, the piezoelectric plates 24 can be disposed in the windows 78 of the thickening sheet 66 over the windows 80 of the insulative sheet 64, such that the surface electrodes 32 are not yet in contact with the underlying conductive sheet 60. In this case, when the laminate is cured, as will be described in further detail below, the surface electrodes 32 will come into direct electrical contact with the underlying conductive sheet 60 through the windows 80. The use of the small conductive sheets 70, however, is preferred, since they ensure that the height of the corresponding layer is uniform and further ensure electrical conductivity between the surface electrodes 32 and the underlying conductive sheet 60.

Next, the other side of the laminate is formed by performing the foregoing steps but in reverse order. In particular, the small conductive sheets 68 are respectively disposed and centered on the piezoelectric plates 24 (FIG. 5g), the insulative sheet 62 is disposed over the thickening sheet 66, such that the small conductive sheets 68 are respectively disposed within windows 76 of the insulative sheet 62 (FIG. 5h), the conductive sheet 58 is disposed over the insulative sheet 62 in contact with the small conductive sheets 68 (sheets 68 shown in phantom) (FIG. 5i), and the outer insulative sheet 54 is disposed over the conductive sheet 58 (FIG. 5j).

The use of the insulative sheet 62 and the small conductive sheets 68 provide the same advantages as the insulative sheet 64 and small conductive sheets 70 provided above; that is, to ensure electrical isolation between the conductive sheets 58, 60, while ensuring electrical conductivity between the surface electrodes 30 (shown in FIG. 2) of the piezoelectric plates 24 and the conductive sheet 58. Again, in an alternative embodiment, the use of the small conductive sheets 70 may be foregone. Also, as previously discussed above with respect to the conductive sheet 60, the conductive sheet 58 has a smaller width, but greater length, than the outer insulative sheet 54, to ensure electrical isolation between the conductive sheet 58 and the environment in which the piezoelectric package 22 is to be mounted, as well as to provide an exposed portion 82 to which the electrical lead 50 (shown in FIG. 2) is to be connected.

After the laminate structure has been laid-up, the movable sheet 72 with the laminate structure is placed into an oven and cured. During the curing process, the resin from the insulative sheets 54, 56, 62, 64, 66 flows to coat the fibers within these sheets and fill in any gaps within the structure that would otherwise form air pockets within the piezoelectric package 22. The resin then polymerizes into a rigid composite structure. As a result of this process, the outer insulative sheets 54, 56 form the outer structural material 40, the conductive sheets 58, 60 form the electrically conductive layers 34, 36, the inner insulative sheets 62, 64, as well as the thickening sheet 66, form the inner structural material 38, and the electrically conductive sheets 68, 70 form the vertical conductors 46, 48, as shown in FIG. 3. Significantly, because the conductive sheets 58, 60 are porous, the resin from these sheets also flows into and polymerizes within the porous structure to strengthen the mechanical connection between the conductive sheets 58, 60 and insulative material.

Preferably, a vacuum seal is provided around the laminate structure (e.g., by using a vacuum bag) during the curing process to enable extraction of unused resin and to produce a thin, low profile piezoelectric package 22. That is, the vacuum seal makes use of external atmospheric pressure to compress the laminate structure and to extract any unwanted air and excess resin. The laminate structure is preferably cured at the temperature and for a duration that is recommended by the manufacturer of the insulative sheets 54, 56, 62, 64, 66. However, care must be taken not to cure the laminate structure at a temperature that is greater than the Curie temperature of the piezoelectric plates 24 above which the piezoelectric properties are lost of the piezoelectric plates 24 (i.e., the dipoles in the piezoelectric plates 24 become randomly oriented, such that the net motion in response to an electrical field becomes zero). To this end, the insulative sheets 54, 56, 62, 64, 66 are selected, such that their recommended curing temperature does not exceed the Curie temperature of the piezoelectric plates 24; for example, at a temperature of 350° F. Notably, the temperature at which the resin polymerizes will depend on the exact composition of the resin. In some embodiments, the resin may polymerize at relatively low temperatures; for example, at room temperature, in which case, the laminate structure need only be heated to room temperature.

After laminate structure of the piezoelectric package 22 has been fabricated and cured, the leads 50, 52 (or alternatively, the connector), can be suitably connected to the respective exposed end portions 42, 44 of the conductive sheets 58, 60. To prevent the resin from flowing into the end portions 42, 44 of the conductive sheets 58, 60 where connection of the leads 50, 52 (or alternatively the connector) is made, solder can be melted into the end portions 42, 44 of the conductive sheets 58, 60 prior to the curing process. Because the solder has a higher melting temperature than does the resin, the solder will remain within the mesh of the conductive sheets 58, 60 during the curing process. Alternatively, tape can be applied to the end portions 42, 44 of the conductive sheets 58, 60 on the respective surfaces on which the leads 50, 52 (or alternatively the connector) are to be attached, so that the resin remains below these contact surfaces during the curing process. Alternatively, any excess resin at the end portions 42, 44 of the conductive sheets 58, 60 can be cleaned off with a suitable tool. Alternatively, the leads 50, 52 (or alternatively the connector) can be connected to the conductive sheets 58, 60 prior to the curing process, in which case, the resin may still flow within the mesh without compromising the electrical connection between the leads 50, 52 and the respective conductive sheets 58, 60. In this manner, no resin needs to be cleaned off of the end portions 42, 44.

At various times between the lay-up of the laminate structure and the connection of the leads 50, 52 to the conductive sheets 58, 60, the assembly can be electrically tested to ensure that the exposed end portions 42, 44 of the conductive sheets 58, 60 are electrically independent from each other (via conductance measurements) and that the piezoelectric plates 24 are properly working and oriented (via capacitance measurements). If conductivity exists between the leads 50, 52, the conductive sheets must be realigned. Small wires can be temporarily soldered to the end portions 42, 44 of the conductive sheets 58, 60 to facilitate the conductivity and capacitance tests. Notably, as the piezoelectric plate 24 becomes more restricted, its capacitance should decrease. For example, the capacitance of the piezoelectric plate 24 by itself should be the highest, with the capacitance gradually dropping as the piezoelectric plate 24 is placed in the lay-up, then in the cured composite, and finally within a container (as will be described in further detail below).

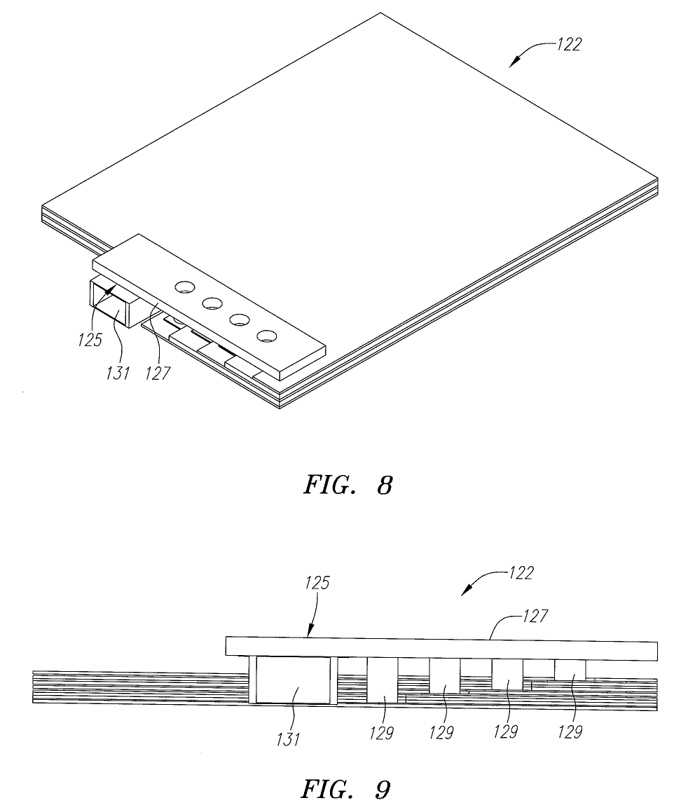

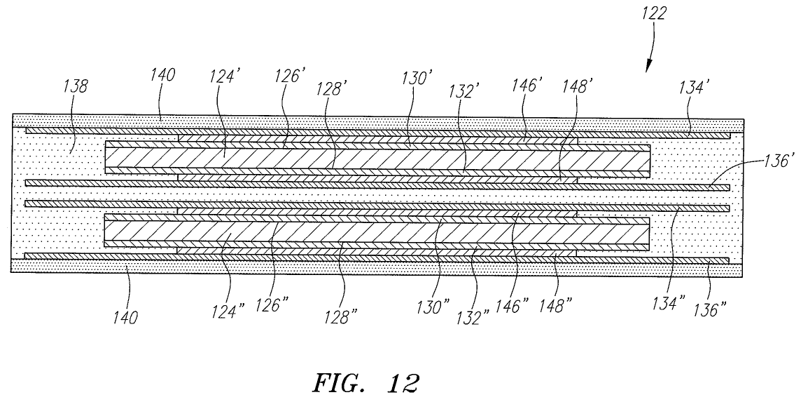

As briefly discussed above, the piezoelectric plates may be arranged within a piezoelectric package in multiple layers. For example, referred now to FIGS. 8-12, another embodiment of a piezoelectric package 122 that can be used as one of the vibration sensing devices 14 or vibration actuating devices 16 (or both) used in the vibration analysis and suppression system 10 illustrated in FIG. 1, will be described. As best illustrated in FIG. 12, which exaggerates the thickness of the layers of the piezoelectric package 122 for purposes of illustration, the piezoelectric package 122 differs from the previously described piezoelectric package 22 in that it comprises multiple layers (in particular, upper and lower layers) of piezoelectric plates, with each layer including a single piezoelectric plate (an upper piezoelectric plate 124′ and a lower piezoelectric plate 124″). Instead of electrical leads, the piezoelectric package 122 includes a connector assembly 125 into which an electrical cable (not shown) can be inserted to operably connect to the piezoelectric plates 124′, 124″.

Significantly, the pair of upper and lower piezoelectric plates 124′, 124″ can be dynamically configured as a unimorph (both piezoelectric plates expand when the same signal is transmitted to the piezoelectric plates) or as a bimorph (one of the piezoelectric plates expands and the other piezoelectric plate contracts when the same signal is transmitted to the piezoelectric plates). Each configuration can occur in an actuator state or in a sensor state.

In the actuator state, the unimorph configuration means that both piezoelectric plates 124′, 124″ expand when the same signal is transmitted to the piezoelectric plates 124′, 124″. In the actuator state, the bimorph configuration means that one of the piezoelectric plates 124′, 124″ expands and the other of the piezoelectric plates 124′, 124″ contracts when the same signal is transmitted to the piezoelectric plates 124′, 124″.

In the sensor state, the unimorph configuration can be thought of as an additive process and the bimorph as a subtractive process. When both piezoelectric plates 124′, 124″ expand, the signal from each is positive and a higher value can be achieved by adding the two signal values (as in the unimorph configuration). When both piezoelectric plates 124′, 124″ contract, the signal from each is negative. A more negative value, i.e. higher in magnitude, can be achieved by adding the two signals (as in the unimorph configuration). When one of the piezoelectric plates 124′, 124″ expands and the other of the piezoelectric plates 124′, 124″ contracts, the signals are positive and negative, respectively. The higher magnitude will be achieved by subtracting these signals (as in the bimorph configuration). The ideal case for a unimorph sensor is one in which both piezoelectric plates 124′, 124″ expand the same amount, and thus, the sum of the individual signals is twice as big as either individual one of the piezoelectric plates 124′, 124″. This same case in bimorph configuration would lead to a signal of 0. The ideal case for a bimorph sensor is one in which one of the piezoelectric plate 124′, 124″ expands as much as the other of the piezoelectric plates 124′, 124″ contracts, and thus, the difference between the individual signals is twice as large in magnitude as either individual one of the piezoelectric plate 124′, 124″. This same case in unimorph configuration would lead to a signal of 0. By correctly selecting the unimorph or bimorph configuration, a more sensitive signal can be achieved.

Any structure undergoing bending has a neutral axis plane, a plane on which no bending stress is experienced. On one side of this plane, the structure expands and on the other side, it contracts. If the sensor is entirely on one side of the neutral axis, a unimorph or extensional configuration is better, as both piezoelectric plates will expand or contract in accordance with the side of the neutral axis on which it resides. With the neutral axis inside the sensor, a bimorph or bending configuration is likely better (though it actually depends on the exact location within the sensor). The location of the neutral axis depends on the boundary conditions, material, and geometry of the structure, among other factors. On-the fly selection of a unimorph or bimorph configuration allows the user to select the most sensitive configuration for the application. Similarly, in an actuator state, the piezoelectric package will be able to induce the most vibration when the correct morphological configuration is selected.

The piezoelectric plates 124′, 124″ are similar in composition and thickness to the piezoelectric plates 24 described above, with the upper piezoelectric plate 124′ having opposing top and bottom planar surfaces 126′, 128′, and the lower piezoelectric plate 124″ having opposing top and bottom planar surfaces 126″, 128″. In the same manner as the surface electrodes 30, 32 can be formed on the planar surfaces 26, 28 of the piezoelectric plates 24 described above, the piezoelectric package 122 further comprises a pair of surface electrodes 130′, 132′ respectively disposed on the planar surfaces 126′, 128′ of the upper piezoelectric plate 124′ and a pair of surface electrodes 130″, 132″ respectively disposed on the planar surfaces 126″, 128″ of the lower piezoelectric plate 124″.

Like the piezoelectric package 22, the piezoelectric package 122 is designed, such that it continues to function even if the piezoelectric plates 124′, 124″ are fractured or otherwise damaged. To this end, the piezoelectric package 122 comprises a pair of electrically conductive layers 134′, 136′ respectively disposed relative to the planar surfaces 126′, 128′ of the upper piezoelectric plate 124′, and a pair of electrically conductive layers 134″, 136″ respectively disposed relative to the planar surfaces 126″, 128″ of the lower piezoelectric plate 124″. As will be discussed in further detail below, the conductive layers 134′, 136′ are electrically coupled to the respective planar surfaces 126′, 128′ of the upper piezoelectric plate 124′ via the surface electrodes 130′, 132′, and the conductive layers 134″, 136″ are electrically coupled to the respective planar surfaces 126″, 128″ of the lower piezoelectric plate 124″ via the surface electrodes 130″, 132″.

In the same manner described above with respect to the conductive layers 34, 36, the conductive layers 134′, 136′, 134″, 136″ are composed of a porous material. Also, the conductive layers 134′, 136′, 134″, 136″ are dimensioned relative to the planar surfaces 126′, 128′, 126″, 128″ of the piezoelectric plates 124′, 124″ in a similar manner as the conductive layers 34, 36 discussed above. That is, the areas of the conductive layers 134′, 136′ are large relative to the respective areas of the planar surfaces 126′, 128′ of the upper piezoelectric plate 124′, and the areas of the conductive layers 134″, 136″ are large relative to the respective areas of the planar surfaces 126″, 128″ of the lower piezoelectric plate 124″. In particular, the ratio of the areas of the conductive layers 134′, 136′ over the respective areas of the planar surfaces 126′, 128′ are equal to or greater than unity, and the ratio of the areas of the conductive layers 134″, 136″ over the respective areas of the planar surfaces 126″, 128″ are equal to or greater than unity.

Again, because an increased surface for electrically coupling the planar surfaces 126′, 128′, 126″, 128″ of the piezoelectric plates 124′, 124″ is provided, the piezoelectric package 122 may still function even if the portions of the conductive layers 134′, 136′, 134″, 136″ and piezoelectric plates 124′, 124″ are damaged. That is, the large area conductive layers 134′, 136′, 134″, 136″ would have to be completely severed for the piezoelectric package 122 to cease functioning properly.

The piezoelectric package 122 further comprises an inner structural material 138 located between the conductive layers 134′, 134″, 136′, 136″, thereby ensuring that the conductive layers 134′, 134″, 136′, 136″ are electrically isolated from each other, and further ensuring that the piezoelectric plates 124′, 124″ are electrically isolated from the environment (e.g., from the host structure 12), thereby preventing electrical shorting. The inner structural material 138 also homogenizes the pressure on the piezoelectric plates 124′, 124″, thereby making microcracks much less likely to form in the piezoelectric plates 124′, 124″.

The piezoelectric package 122 further comprises an outer structural material 140 that encapsulates the conductive layers 134′, 134″, 136′, 136″ (with the exception of contacts 142′, 144′, 142″, 144″), along with the piezoelectric plates 124′, 124″, thereby ensuring that the conductive layers 134′, 134″, 136′, 136″ are electrically isolated from the environment (e.g., from the host structure 12), thereby preventing electrical shorting.

The inner structural material 138 and outer structural material 140 may be composed of the same material as the inner and outer structural materials 38, 40 discussed above

The piezoelectric package 122 further comprises a vertical electrical conductor 146′ extending through the inner structural material 138 between the conductive layer 134′ and the surface electrode 130′ disposed on the upper piezoelectric plate 124′, a vertical electrical conductor 148′ extending through the inner structural material 138 between the conductive layer 136′ and the surface electrode 132′ disposed on the upper piezoelectric plate 124′, a vertical electrical conductor 146″ extending through the inner structural material 138 between the conductive layer 134″ and the surface electrodes 130″ disposed on the lower piezoelectric plate 124″, and a vertical electrical conductor 148″ extending through the inner structural material 138 between the conductive layer 136″ and the surface electrode 132″ disposed on the lower piezoelectric plate 124.″ Notably, the cross-sectional areas of the vertical electrical conductors 146′, 148′, 146″, 148″ are respectively less than the areas of the planar surfaces 126′, 128′, 126″, 128″ of the respective piezoelectric plates 124′, 124″, so that the inner structural material 138 is disposed on the outer peripheral regions of the surface electrodes 128′, 130′, 128″, 130″. In this manner, electrical isolation between the conductive layers 134′, 136′, 134″, 136″ at the edges of the piezoelectric plates 124′, 124″ is ensured.

Referring specifically to FIG. 11, the piezoelectric package 122 further comprises electrical contacts 142′, 144′, 142″, 144″ that emerge from one side of the piezoelectric package 122 for connection to the connector assembly 125 (shown in FIGS. 8-10), as will be discussed in further detail below. In the embodiment illustrated in FIG. 11, the contacts 142′, 144′, 142″, 144″ take the form of tabs that respectively extend from the edges of the conductive layers 134′, 134″, 136′, 136″ (shown in FIG. 12). In alternative embodiments, the contacts 142′, 144′, 142″, 144″ may emerge from multiple sides of the piezoelectric package, in which case, the piezoelectric package 122 may include multiple connectors (not shown), thereby providing for a more flexible implementation or integration of the piezoelectric package 122, as well as making the use of the piezoelectric package 122 more ubiquitous. The piezoelectric package 122 further comprises four electrically insulative tabs 143′, 145′, 143″, 145″ extending from one side of the piezoelectric package 122 underneath the respective contacts 142′, 144′, 142″, 144″, thereby providing a substrate for supporting the contacts 142′, 144′, 142″, 144″, as well as ensuring that the contacts 142′, 144′, 142″, 144″ are electrically isolated from each other. The tabs 143′, 145′, 143″, 145″ may be composed of the same material as the inner and outer structural materials 38, 40 discussed above.

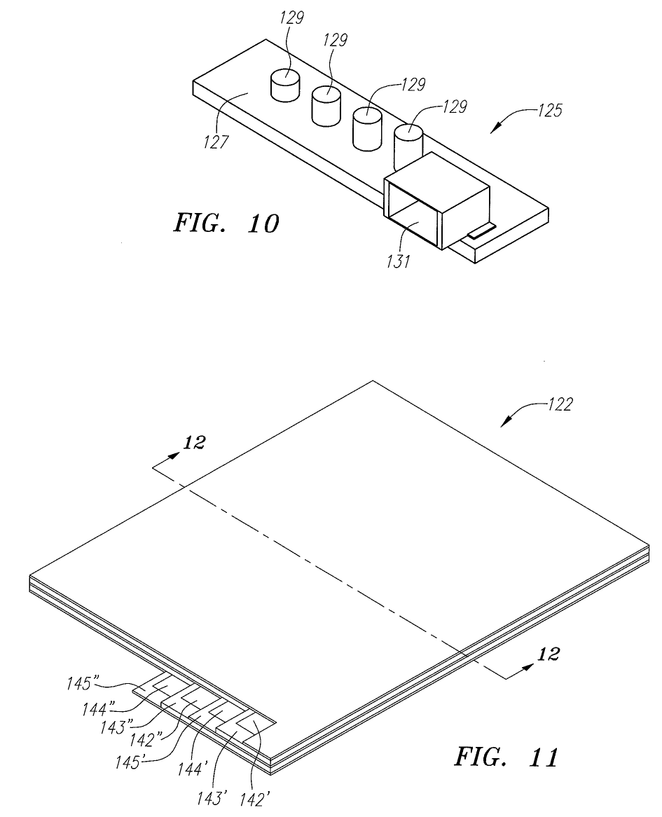

Referring to FIGS. 9 and 10, the connector assembly 125 comprises a printed circuit board 127, four terminals 129 mounted onto the printed circuit board 127, and a connector 131 mounted to the printed circuit board 127 in electrical communication with the terminals 129. As shown in FIGS. 9 and 10, the lengths of the terminals 129 gradually increase for connection to the respective contacts 142′, 144′, 142″, 144″ (shown in FIG. 11), which have gradually increasing heights. While not illustrated, the printed circuit board 127 includes electrical traces (not shown) that are coupled between the terminals 129 and contacts (not shown) within the connector 131. The terminals 129 of the connector assembly 125 are respectively connected to the contacts 142′, 144′, 142″, 144″ (shown in FIG. 11) using suitable means, such as soldering or welding. Thus, the connector 131, and any suitable cable mated with the connector 131, is independently electrically coupled to the respective planar surfaces 126′, 128′, 126″, 128″ of the piezoelectric plates 124′, 124″ via the conductive layers 134′, 136′, 134″, 136″ and surface electrodes 130′ 132′, 130″, 132″ (shown in FIG. 12). While the printed circuit board 127 is illustrated as having a size just large enough to span the contacts 142′, 144′, 142″, 144″, in an alternative embodiment, the printed circuit board 127 may be large enough to span the entire laminate structure, thereby providing a uniform surface along the entire top of the laminate structure.

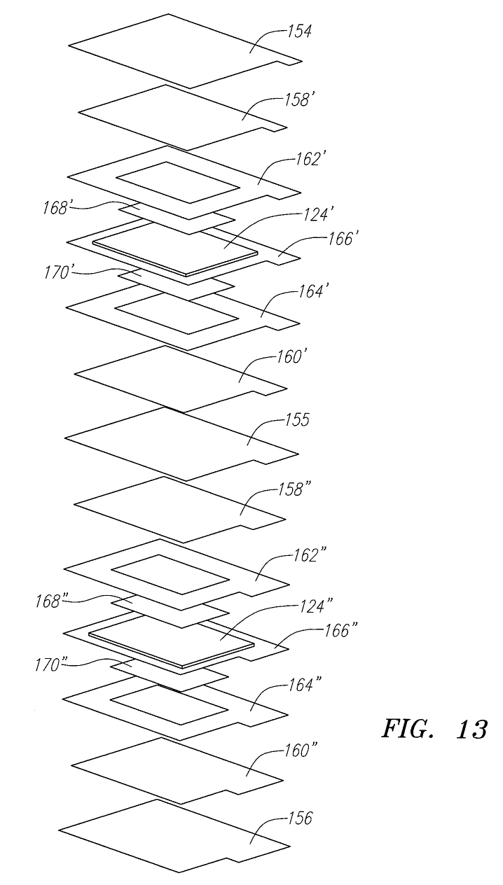

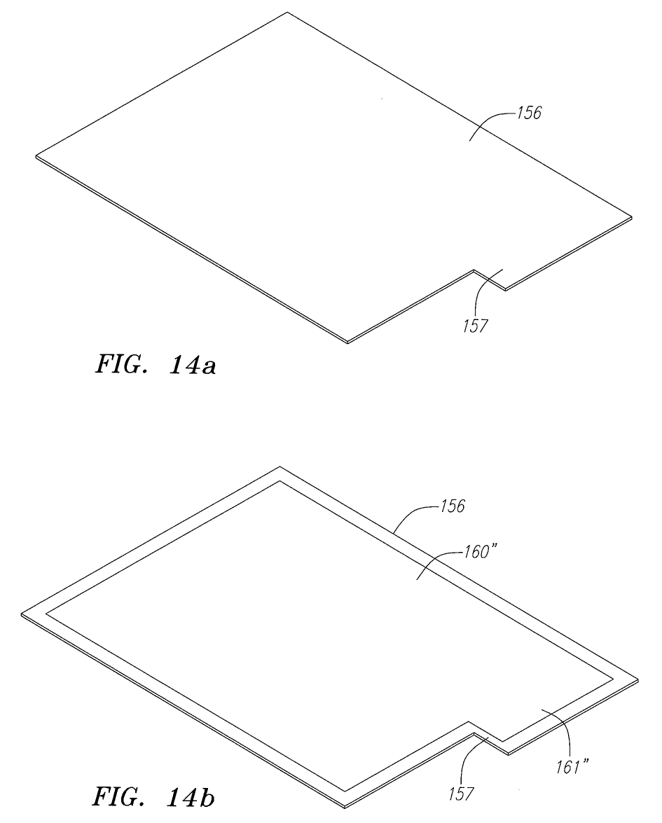

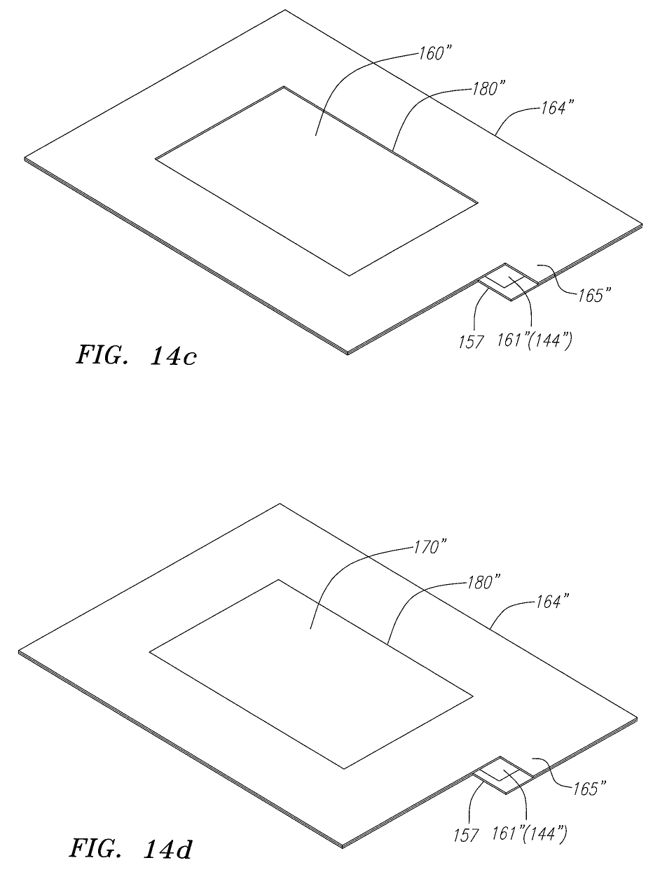

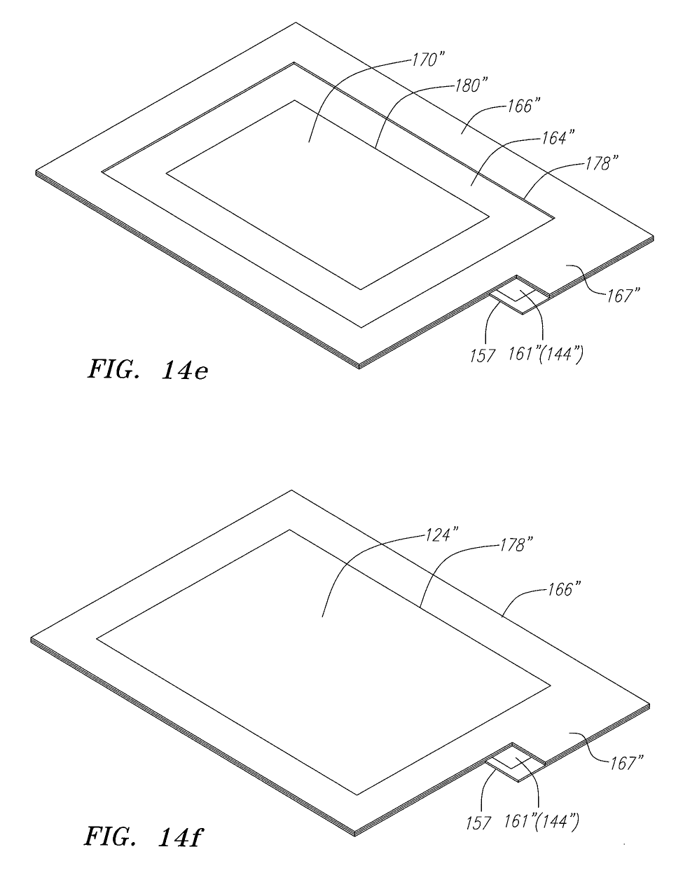

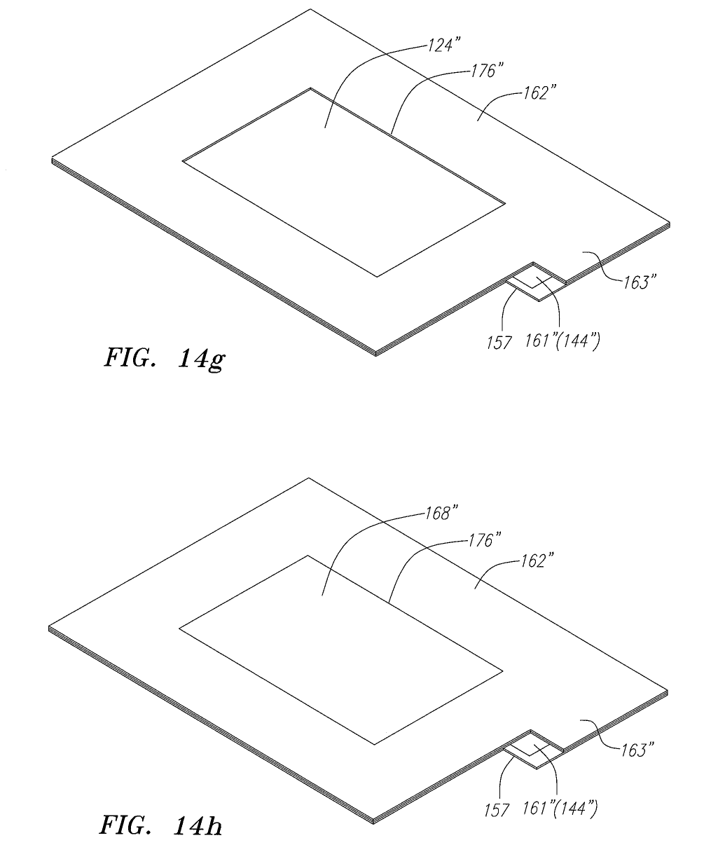

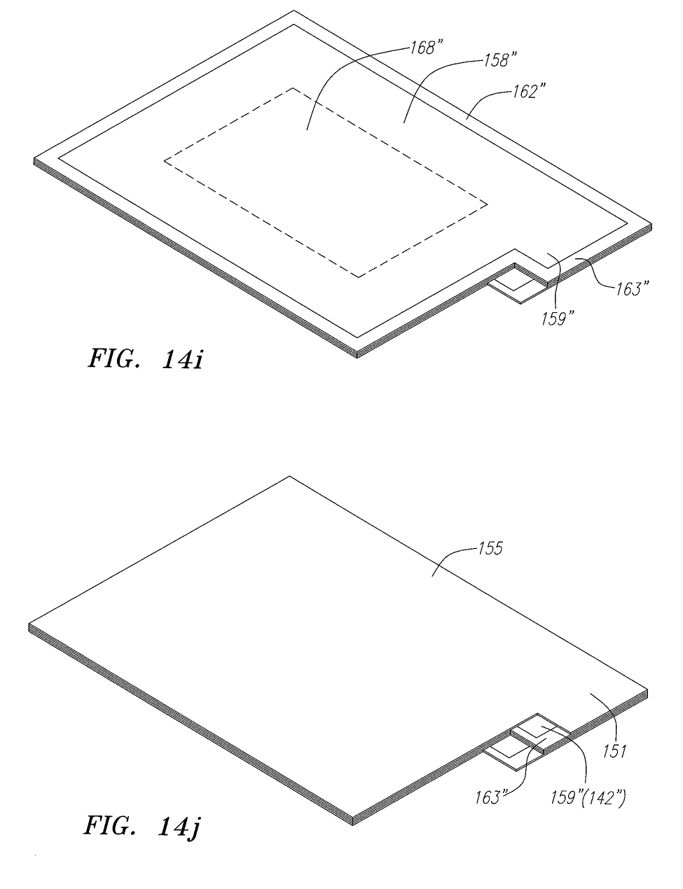

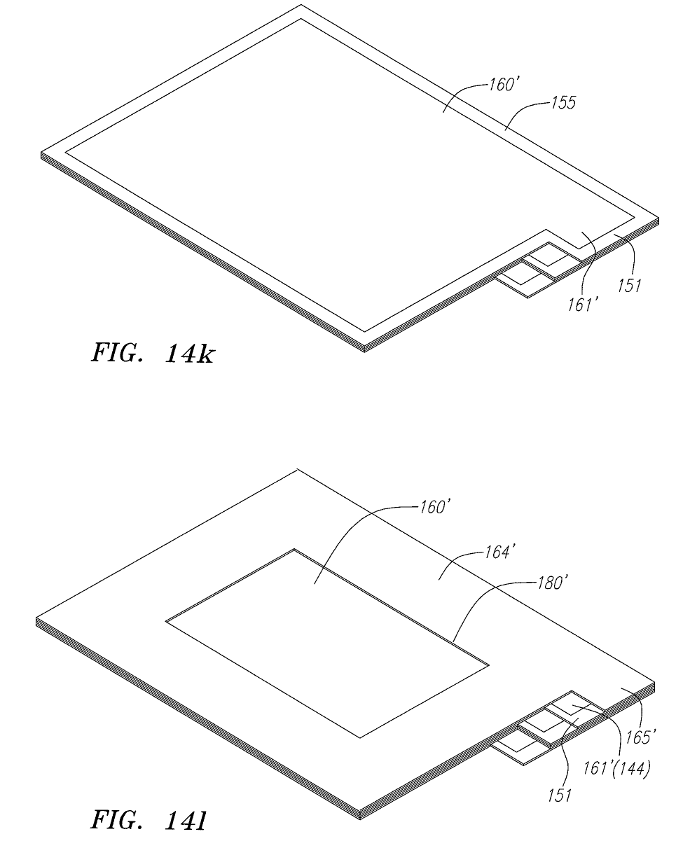

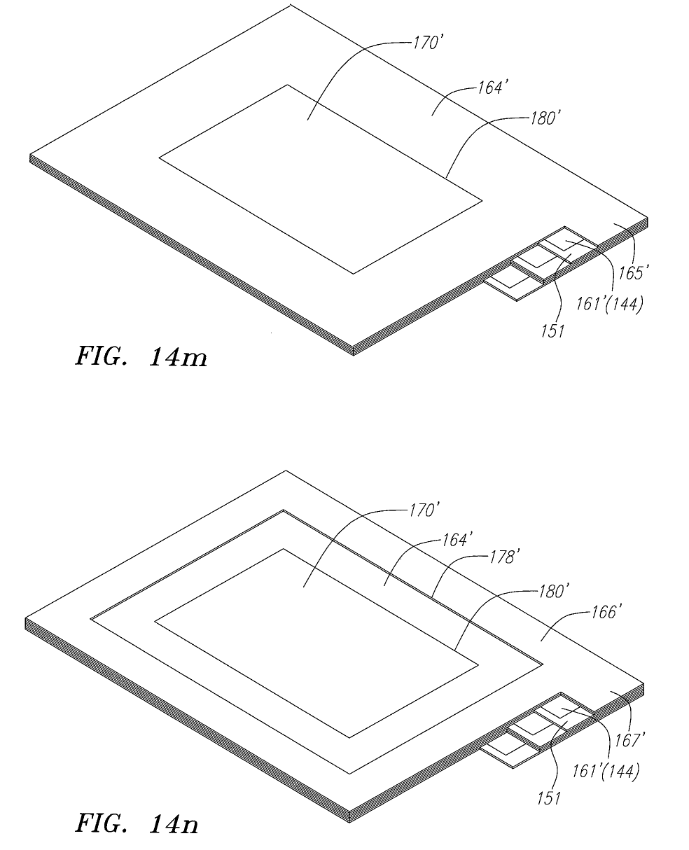

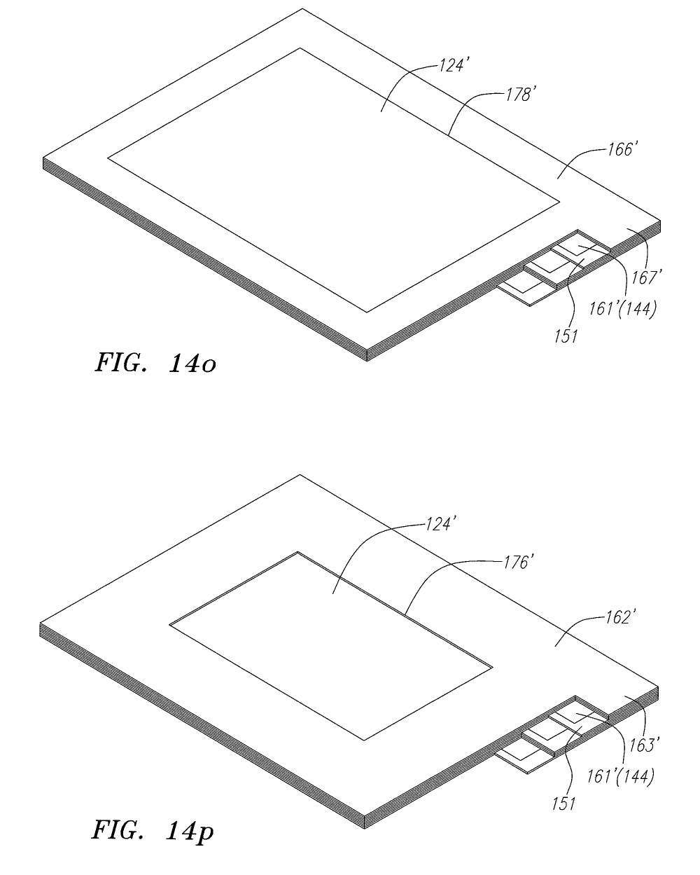

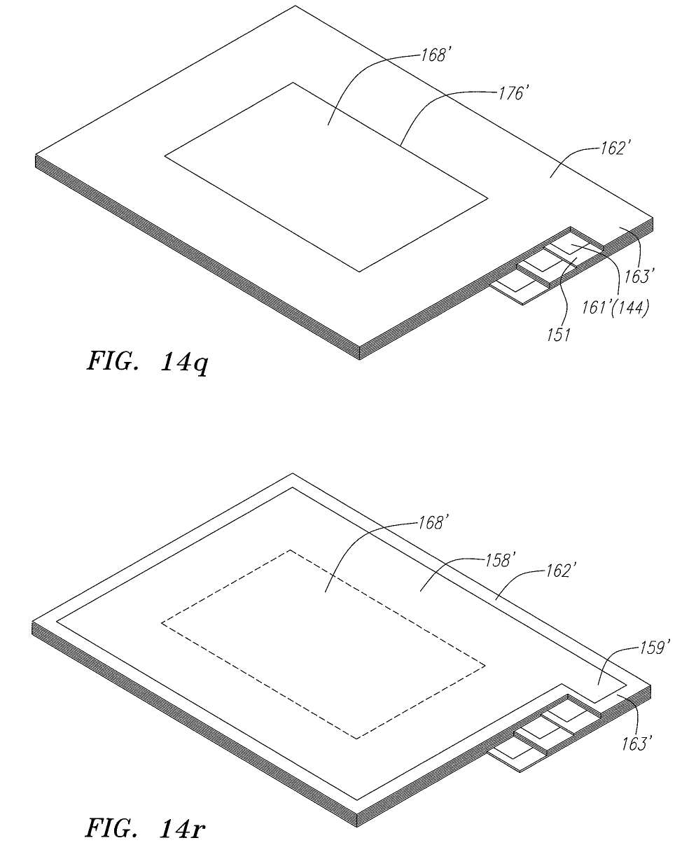

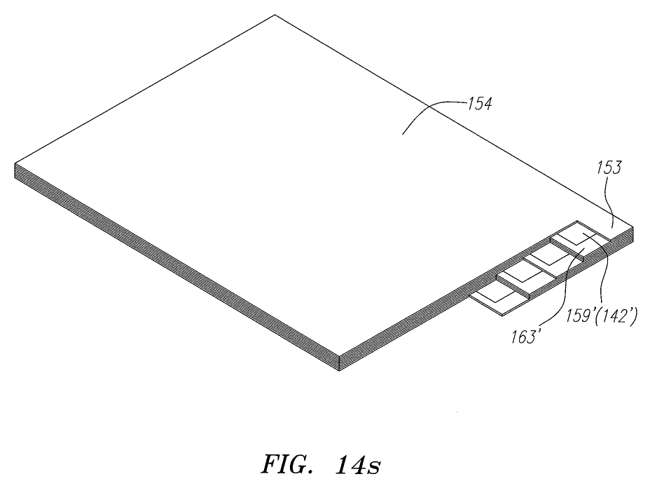

Having described its structure, a method of manufacturing the piezoelectric package 122 will be described with respect to FIG. 13 and FIGS. 14a-14s. In this method, the piezoelectric package 122 is created from a multilayer laminate comprising a layup of two piezoelectric plates 124′, 124″, three electrically insulative sheets 154, 155, 156, four electrically conductive sheets 158′, 160′, 158″, 160″, four electrically insulative sheets 162′, 164′, 162″, 164″, two thickening sheets 166′, 166″, and four small electrically conductive sheets 168′, 170′, 168″, 170″. As will be described in further detail below, this layup is then cured to form a composite structure of the piezoelectric package 122.

The insulative sheets 154, 155, 156, 162′, 164′, 162″, 164″ and the thickening sheets 166′, 166″ may be composed of the same material and have the same thicknesses as the insulative sheets 54, 56, 62, 64 and thickening sheet 66 used to form the piezoelectric package 22, the conductive sheets 158′, 160′, 158″, 160″ can be composed of the same material and have the same thicknesses as the conductive sheets 58, 60 used to form the piezoelectric package 22, and the conductive sheets 168′, 170′, 168″, 170″ can be composed of the same material and have the same thicknesses as the conductive sheets 68, 70 used to form the piezoelectric package 22.

In the same manner described above with the conductive sheets 58, 60, the sizes of the conductive sheets 158′, 160′, 158″, 160″ are smaller than the sizes of the insulative sheets 154, 155, 156, 162′, 164′, 162″, 164″ to maximize electrical isolation (i.e., prevent shorting) between the conductive sheets 158′, 160′, 158″, 160″ themselves, and between the conductive sheets 158′, 160′, 158″, 160″ and the environment. In the same manner described above with respect to the windows of the insulative sheets 62, 64, the insulative sheets 162′, 164′, 162″, 164″ have windows (described below) that are smaller than the piezoelectric plates 124′, 124″ to prevent the conductive sheets 158′, 160′, 158″, 160″ from conducting electricity to and from nothing other than the center of the piezoelectric plates 124′, 124″ via the respective small conductive sheets 168′, 170′, 168″, 170″. The windows have the same sizes as the respective conductive sheets 168′, 170′, 168″, 170″ to minimize any discontinuities between the conductive sheets 168′, 170′, 168″, 170″ and the insulative sheets 162′, 164′, 162″, 164″. In the same manner described above with respect to the layup of the piezoelectric package 22, connection between the piezoelectric plates 124′, 124″ and the conductive sheets 158′, 160′, 158″, 160″ is easily accomplished as part of the process of disposing the different layers of the structure over one another, thereby avoiding the need to separately make connections to the piezoelectric plates 124′, 124″.

The main differences between the sheets of the layup illustrated in FIG. 13 and the sheets of the layup illustrated in FIG. 4 is that they must accommodate two layers of piezoelectric plates (as opposed to a single layer), and the sheets of the layup illustrated in FIG. 13 include tabs of varying widths that will result in distribution of the contacts 142′, 144′, 142″, 144″ (shown in FIG. 11) along the edge of the piezoelectric package 122.

The method of manufacturing the piezoelectric package 122 is first initiated by placing the insulative sheet 156 onto a movable, flat, supporting sheet (similar to that shown in FIG. 5a) that can be placed into and removed from a curing oven (FIG. 14a). As there shown, the insulative sheet 156 includes a tab 157 having a relatively wide dimension. Next, the conductive sheet 160″ is disposed over the insulative sheet 156 (FIG. 14b). The conductive sheet 160′ has a tab 161″, a portion of which will form the fourth contact 144″ of the piezoelectric package 122. Next, the insulative sheet 164″ is disposed over the conductive sheet 160″ (FIG. 14c). As shown, a cutout window 180″ is formed through the insulative sheet 164″ corresponding to the center of the lower piezoelectric plate 124″. The insulative sheet 164″ has a tab 165″ having a width that is slightly less than the width of the tab 161″ of the conductive sheet 160″ in order to expose a portion of the tab 161″ to form the fourth contact 144″.

Next, the small conductive sheet 170″ is disposed within the window 180″ of the insulative sheet 164″ in contact with the underlying conductive sheet 160″, such that the small conductive sheet 170″ is in the same plane as the insulative sheet 164″ (FIG. 14d), and the thickening sheet 166″ is disposed over the insulative sheet 164″ (FIG. 14e). In the illustrated embodiment, the thickening sheet 166″ has a tab 167″ having the same width as the underlying tab 165″ of the insulative sheet 164″. As shown, a window 178″ is formed through the thickening sheet 166″.

Then, the lower piezoelectric plate 124″ is disposed within the window 178″ of the thickening sheet 166″ in contact with the small conductive sheet 170″ (FIG. 14f), and the insulative sheet 162″ is disposed over the thickening sheet 166″ (FIG. 14g). In the illustrated embodiment, the insulative sheet 162″ has a tab 163″ having the same width as the tab 167″ of the thickening sheet 166″. As shown, a window 176″ is formed through the insulative sheet 162″. Next, the small conductive sheet 168″ is disposed within the window 176″ of the insulative sheet 162″ (FIG. 14h), and the conductive sheet 158″ is disposed over the insulative sheet 162″ in contact with the small conductive sheet 168″ (FIG. 14i). The conductive sheet 158″ has a tab 159″, a portion of which will form the second contact 142″ of the piezoelectric package 122.

Next, the insulative sheet 155 is disposed over the conductive sheet 158″ (FIG. 14j). The insulative sheet 155 has a tab 151 that has a width that is slightly less than the width of the tab 159″ of the conductive sheet 158″ in order to expose a portion of the tab 159″ to form the third contact 142″. Then, the conductive sheet 160′ is disposed over the insulative sheet 155 (FIG. 14k). The conductive sheet 160′ has a tab 161′, a portion of which will form the third contact 142″ of the piezoelectric package 122. Next, the insulative sheet 164′ is disposed over the conductive sheet 160′ (FIG. 141). As shown, a cutout window 180′ is formed through the insulative sheet 164′ corresponding to the center of the upper piezoelectric plate 124′. The insulative sheet 164′ has a tab 165′ having a width that is slightly less than the width of the tab 161′ of the conductive sheet 160′ in order to expose a portion of the tab 161′ to form the second contact 144′.

Next, the small conductive sheet 170′ is disposed within the window 180′ of the insulative sheet 164′ in contact with the underlying conductive sheet 160′, such that the small conductive sheet 170′ is in the same plane as the insulative sheet 164′ (FIG. 14m), and the thickening sheet 166′ is disposed over the insulative sheet 164′ (FIG. 14n). In the illustrated embodiment, the thickening sheet 166′ has a tab 167′ having the same width as the underlying tab 165′ of the insulative sheet 164′. As shown, a window 178′ is formed through the thickening sheet 166′.

Then, the upper piezoelectric plate 124′ is disposed within the window 178′ of the insulative sheet 166′ in contact with the small conductive sheet 170′ (FIG. 14o), and the insulative sheet 162′ is disposed over the thickening sheet 166′ (FIG. 14p). In the illustrated embodiment, the insulative sheet 162′ has a tab 163′ having the same width as the tab 167′ of the thickening sheet 166′. As shown, a window 176′ is formed through the insulative sheet 162′. Next, the small conductive sheet 168′ is disposed within the window 176′ of the insulative sheet 162′ (FIG. 14q), and the conductive sheet 158′ is disposed over the insulative sheet 162′ in contact with the small conductive sheet 168′ (FIG. 14r). The conductive sheet 158′ has a tab 159′, a portion of which will form the first contact 142′ of the piezoelectric package 122. Lastly, the insulative sheet 154 is disposed over the conductive sheet 158′ (FIG. 14s). The insulative sheet 154 has a tab 153 that has a width that is slightly less than the width of the tab 159′ of the conductive sheet 158′ in order to expose a portion of the tab 159′ to form the first contact 142′.

After the laminate structure has been laid-up, the movable sheet (not shown) with the laminate structure is placed into an oven and cured. During the curing process, the resin from the insulative sheets 154, 155, 156, 162′, 164′, 166′, 162″, 164″, 166″ flows to coat the fibers within these sheets and fill in any gaps within the structure that would otherwise form air pockets within the piezoelectric package 122. The resin then polymerizes into a rigid composite structure. As a result of this process, the outer insulative sheets 154, 156 form the outer structural material 140, the conductive sheets 158′, 160′, 158″, 160″ respectively form the electrically conductive layers 134′, 134″, 136′, 136″, the inner insulative sheets 155, 162′, 164′, 162″, 164″, as well as the thickening sheets 166′, 166″, form the inner structural material 138, and the electrically conductive sheets 168′, 170′, 168″, 170″ form the vertical conductors 146′, 148′, 146″, 148″, as shown in FIG. 12. Significantly, because the conductive sheets 158′, 160′, 158″, 160″ are porous, the resin from these sheets also flows into and polymerizes within the porous structure to strengthen the mechanical connection between the conductive sheets 158′, 160′, 158″, 160″ and insulative material. The laminate structure of the piezoelectric package 122 can be vacuum sealed and cured in the same manner described above with respect to the laminate structure of the piezoelectric package 22.

Referring back to FIGS. 9 and 10, after laminate structure of the piezoelectric package 122 has been fabricated and cured, the terminals 129 of the connector assembly 125 can be respectively connected to the contacts 142′, 144′, 142″, 144″, e.g., via soldering or welding. In one method, the terminals 129 are soldered to the contacts 142′, 144′, 142″, 144″, and then the printed circuit board 127 is soldered to the terminals 129. In the same manner discussed above with respect to the assembly of the leads 50, 52 onto the end portions 42, 44 of the conductive sheets 58, 60, solder or tape can be applied to the contacts 142′, 144′, 142″, 144″ prior to curing to prevent the resin from being disposed on the surfaces of the contacts 142′, 144′, 142″, 144″, or any excess resin on the surfaces of the contacts 142′, 144′, 142″, 144″ can be cleaned off with a tool, or the connector assembly 125 can be connected to the contacts 142′, 144′, 142″, 144″ prior to the curing process. Again, at various times between the lay-up of the laminate structure and the connection of the connector assembly 125 to the contacts 142′, 144′, 142″, 144″, the assembly can be electrically tested to ensure that the contacts 142′, 144′, 142″, 144″ are electrically independent from each other (via conductance measurements) and that the piezoelectric plates 124′, 124″ are properly working (via capacitance measurements).

While the piezoelectric package 22 has been described as having a single layer of multiple piezoelectric plates 24, and the piezoelectric package 122 has been described as having multiple layers with single piezoelectric plates 24 each, piezoelectric packages fabricated in accordance with the present inventions may have multiple layers with multiple piezoelectric elements each.

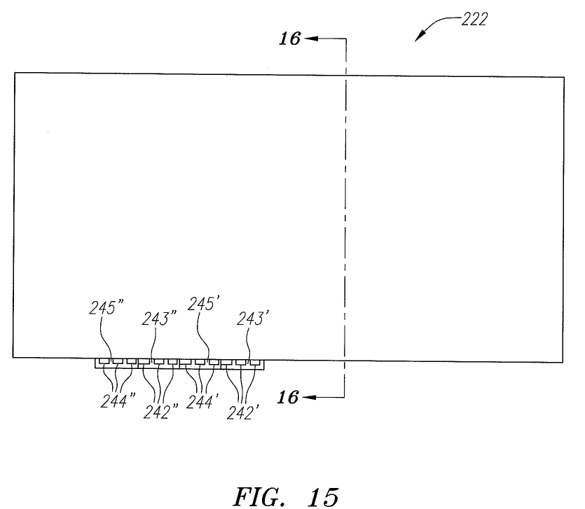

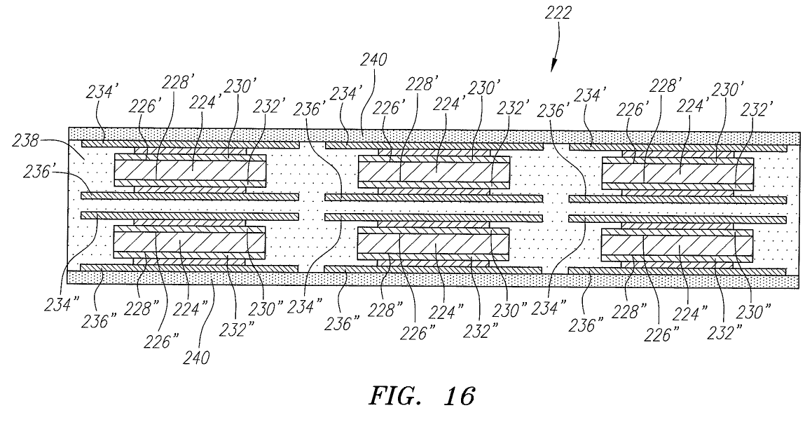

In particular, and with reference to FIGS. 15 and 16, still another embodiment of a piezoelectric package 222 that can be used as one of the vibration sensing devices 14 or vibration actuating devices 16 (or both) used in the vibration analysis and suppression system 10 illustrated in FIG. 1, will be described. The piezoelectric package 222 differs from the previously described piezoelectric package 122 in that it comprises multiple piezoelectric plates on multiple layers, and in this case, three upper piezoelectric plates 224′ and three lower piezoelectric plates 224″.

The piezoelectric plates 224′, 224″ are similar in composition and thickness to the piezoelectric plates 24 described above, with each of the upper piezoelectric plates 224′ having opposing planar surfaces 226′, 228′, and each of the lower piezoelectric plates 224″ having opposing planar surfaces 226″, 228″. In the same manner as the surface electrodes 30, 32 can be formed on the planar surfaces 26, 28 of the piezoelectric plates 24 described above, the piezoelectric package 222 further comprises a pair of surface electrodes 230′, 232′ respectively disposed on the planar surfaces 226′, 228′ of each of the upper piezoelectric plates 224′, and a pair of surface electrodes 230″, 232″ respectively disposed on the planar surfaces 226″, 228″ of each of the lower piezoelectric plates 224″.

Like the piezoelectric package 22, the piezoelectric package 222 is designed, such that it continues to function even if piezoelectric plates 224′, 224″ are fractured or otherwise damaged. To this end, the piezoelectric package 222 further comprises a pair of electrically conductive layers 234′, 236′ respectively disposed relative to the planar surfaces 226′, 228′ of each of the upper piezoelectric plates 224′, and a pair of electrically conductive layers 234″, 236″ respectively disposed relative to the planar surfaces 226″, 228″ of each of the lower piezoelectric plates 224″. The conductive layers 234′, 236′ are electrically coupled to the respective planar surfaces 226′, 228′ of the upper piezoelectric plate 224′ via the surface electrodes 230′, 232′, and the conductive layers 234″, 236″ are electrically coupled to the respective planar surfaces 226″, 228″ of the lower piezoelectric plate 124″ via the surface electrodes 130″, 132″. The conductive layers 234′, 236′, 234″, 236″ are similar to the conductive layers 134′, 136′, 134″, 136″ described above with respect to the piezoelectric package 122. However, each of the conductive layers 234′, 236′ is divided into three electrically isolated segments that are respectively coupled to the three upper piezoelectric plates 224′, and each of the conductive layers 234″, 236″ is divided into three electrically isolated segments that are respectively coupled to the three lower piezoelectric plates 224″, as shown in FIG. 16.

In the same manner described above with respect to the conductive layers 34, 36, the conductive layers 234′, 236′, 234″, 236″ are composed of a porous material. Also, the segments of the conductive layers 234′, 236′, 234″, 236″ are dimensioned relative to the planar surfaces 226′, 228′, 226″, 228″ of the piezoelectric plates 224′, 224″ in a similar manner as the conductive layers 34, 36 discussed above. That is, the areas of the segments of the conductive layers 234′, 236′ are large relative to the respective areas of the planar surfaces 126′, 128′ of the upper piezoelectric plates 124′, and the areas of the segments of the conductive layers 134″, 136″ are large relative to the respective areas of the planar surfaces 126″, 128″ of the lower piezoelectric plates 124″. In particular, the ratio of the areas of the segments of the conductive layers 134′, 136′ over the respective areas of the planar surfaces 126′, 128′ are equal to or greater than unity, and the ratio of the areas of the segments of the conductive layers 134″, 136″ over the respective areas of the planar surfaces 126″, 128″ are equal to or greater than unity.

Again, because an increased surface for electrically coupling the planar surfaces 226′, 228′, 226″, 228″ of the piezoelectric plates 224′, 224″ is provided, the piezoelectric package 222 may still function even if the portions of the segments of the conductive layers 234′, 236′, 234″, 236″ and piezoelectric plates 224′, 224″ are damaged. That is, the large area conductive segments of the layers 234′, 236′, 234″, 236″ would have to be completely severed for the piezoelectric package 222 to cease functioning properly.

The piezoelectric package 222 further comprises an inner structural material 238 located between the conductive layers 234′, 234″, 236′, 236″, thereby ensuring that the conductive layers 234′, 234″, 236′, 236″ are electrically isolated from each other, and further ensuring that the piezoelectric plates 224′, 224″ are electrically isolated from the environment (e.g., from the host structure 12), thereby preventing electrical shorting. The inner structural material 238 also homogenizes the pressure on the piezoelectric plates 224′, 224″, thereby making microcracks much less likely to form in the piezoelectric plates 224′, 224″.

The piezoelectric package 222 further comprises an outer structural material 240 that encapsulates the conductive layers 234′, 234″, 236′, 236″ (with the exception of the contacts 242′, 244′, 242″, 244″), along with the piezoelectric plates 224′, 224″, thereby ensuring that the conductive layers 234′, 234″, 236′, 236″ are electrically isolated from the environment (e.g., from the host structure 12), thereby preventing electrical shorting.

The inner structural material 238 and outer structural material 240 may be composed of the same material as the inner and outer structural materials 38, 40 discussed above.

The piezoelectric package 222 further comprises three vertical electrical conductors 246′ respectively extending through the inner structural material 238 between the segments of the conductive layers 234′ and the surface electrodes 230′ disposed on the upper piezoelectric plates 224′, three vertical electrical conductors 248′ respectively extending through the inner structural material 238 between the segments of the conductive layer segments 236′ and the surface electrodes 232′ disposed on the upper piezoelectric plates 224′, three vertical electrical conductors 246″ respectively extending through the inner structural material 238 between the segments of the conductive layer segments 234″ and the surface electrodes 230″ disposed on the lower piezoelectric plates 224″, and three vertical electrical conductors 248″ respectively extending through the inner structural material 238 between the conductive layer segments 236″ and the surface electrodes 232″ disposed on the lower piezoelectric plates 224″. Notably, the cross-sectional areas of the vertical electrical conductors 246′, 248′, 246″, 248″ are respectively less than the areas of the planar surfaces 226′, 228′ 226″, 228″ of the respective piezoelectric plates 224′, 224″, so that the inner structural material 238 is disposed on the outer peripheral regions of the surface electrodes 230′, 232′, 230″, 232″. In this manner, electrical isolation between the conductive layers 234′, 236′, 234″, 236″ at the edges of the piezoelectric plates 224′, 224″ is ensured.

Referring specifically to FIG. 15, the piezoelectric package 222 further comprises four sets of electrical contacts 242′, 244′, 242″, 244″ that emerge from one side of the piezoelectric package 222 for connection to the connector assembly (not shown), which can be the same as the connector assembly 125 described above with respect to the piezoelectric package 122. The three contacts of the first set 242′ are respectively coupled to the tops of the three upper piezoelectric plates 224′, the three contacts of the second set 244′ are respectively coupled to the bottoms of the three upper piezoelectric plates 224′, the three contacts of the third set 242″ are coupled to the tops of the three lower piezoelectric plates 224″, and the contacts of the fourth set 244″ are coupled to the bottoms of the three lower piezoelectric plates 224″. In the embodiment illustrated in FIG. 15, the contacts 242′, 244′, 242″, 244″ take the form of tabs that are extensions of the conductive layers 234′, 234″, 236′, 236″. In alternative embodiments, the sets of contacts 242′, 244′, 242″, 244″ may emerge from multiple sides of the piezoelectric package, in which case, the piezoelectric package 222 may include multiple connectors (not shown), thereby providing for a more flexible implementation or integration of the piezoelectric package 222, as well as making the use of the piezoelectric package 222 more ubiquitous.

The piezoelectric package 222 further comprises four electrically insulative tabs 243′, 245′, 243″, 245″ extending from one side of the piezoelectric package 222 underneath the respective sets of contacts 242′, 244′, 242″, 244″, thereby providing a substrate for supporting the contact sets 242′, 244′, 242″, 244″, as well as ensuring that the contacts 242′, 244′, 242″, 244″ are electrically isolated from each other. The tabs 243′, 245′, 243″, 245″ may be composed of the same material as the inner and outer structural materials 38, 40 discussed above.

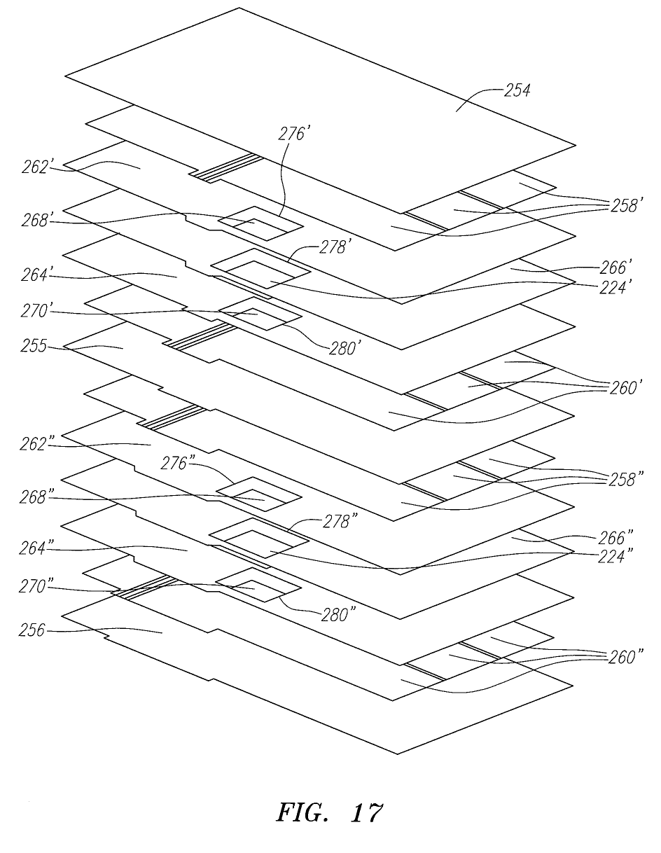

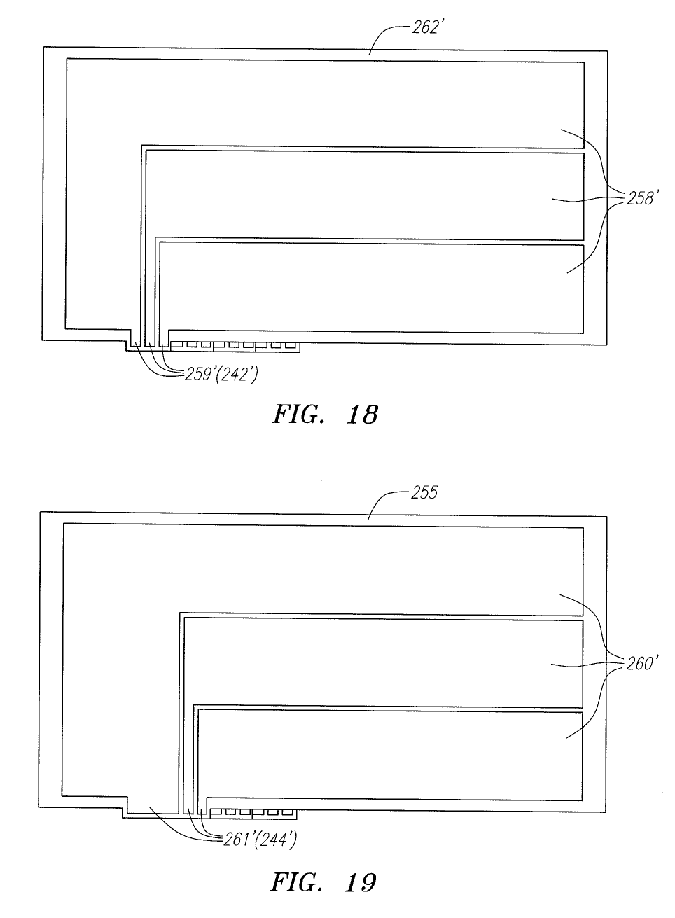

Referring to FIG. 17, the piezoelectric package 222 is created from a multilayer laminate comprising a layup of two sets of three piezoelectric plates 224′, 224″, three electrically insulative sheets 254, 255, 256, four sets of electrically conductive sheets 258′, 260′, 258″, 260″, four electrically insulative sheets 262′, 264′, 262″, 264″, two thickening sheets 266′, 266″, and four sets of small electrically conductive sheets 268′, 270′, 268″, 270″.

The insulative sheets 254, 255, 256, 262′, 264′, 262″, 264″ and the thickening sheets 266′, 266″ may be composed of the same material and have the same thicknesses as the insulative sheets 54, 56, 62, 64 and thickening sheet 66 used to form the piezoelectric package 22, the sets of conductive sheets 258′, 260′, 258″, 260″ can be composed of the same material and have the same thicknesses as the conductive sheets 58, 60 used to form the piezoelectric package 22, and the sets of conductive sheets 268′, 270′, 268″, 270″ can be composed of the same material and have the same thicknesses as the conductive sheets 68, 70 used to form the piezoelectric package 22.

In many respects, the sheets of the layup for the piezoelectric package 222 are similar to the sheets of the layup for the piezoelectric package 122. The sheets of the piezoelectric package 222 differ from the sheets of the piezoelectric package 122, however, in that each set of conductive sheets 258′, 260′, 268′, 270′ includes three sheets that are respectively associated with the three upper piezoelectric plates 224′ (as opposed to single sheets that are associated with a single upper piezoelectric plate), and each set of conductive sheets 258″, 260″, 268″, 270″ includes three sheets that are respectively associated with the there lower piezoelectric plates 224″ (as opposed to single sheets that are associated with a single lower piezoelectric plate).

Furthermore, each of the insulative sheets 262′, 264′ and thickening sheet 266′ includes three windows (three windows 276′, three windows 280′, and three windows 278′) respectively associated with the three upper piezoelectric plates 224′ (as opposed to single windows that are associated with a single upper piezoelectric plate), and each of the insulative sheets 262″, 264″ and thickening sheet 266″ includes three windows (three windows 276″, three windows 280″, and three windows 278″) respectively associated with the three lower piezoelectric plates 224″ (as opposed to single windows that are associated with a single lower piezoelectric plate).

In the same manner described above with the conductive sheets 58, 60, the total set sizes of the conductive sheets 258′, 260′, 258″, 260″ are smaller than the sizes of the insulative sheets 254, 255, 256, 262′, 264′, 262″, 264″ to maximize electrical isolation (i.e., prevent shorting) between the sets of conductive sheets 258′, 260′, 258″, 260″ themselves, and between the sets of conductive sheets 258′, 260′, 258″, 260″ and the environment. In the same manner described above with respect to the windows of the insulative sheets 62, 64, the windows 276′, 280′, 276″, 280″ of the insulative sheets 262′, 264′, 262″, 264″ are smaller than the piezoelectric plates 224′, 224″ to prevent the conductive sheet sets 258′, 260′, 258″, 260″ from conducting electricity to and from nothing other than the centers of the piezoelectric plates 224′, 224″ via the respective conductive sheet sets 268′, 270′, 268″, 270″. The windows 276′, 280′, 276″, 280″ of the insulative sheets 262′, 264′, 262″, 264″ have the same sizes as the respective conductive sheets 268′, 270′, 268″, 270″ to minimize any discontinuities between the conductive sheets 268′, 270′, 268″, 270″ and the insulative sheets 262′, 264′, 262″, 264″. In the same manner described above with respect to the layup of the piezoelectric package 222, connection between the piezoelectric plates 224′, 224″ and the conductive sheets 258′, 260′, 258″, 260″ is easily accomplished as part of the process of disposed the different layers of the structure over one another, thereby avoiding the need to separately make connections to the piezoelectric plates 224′, 224″.

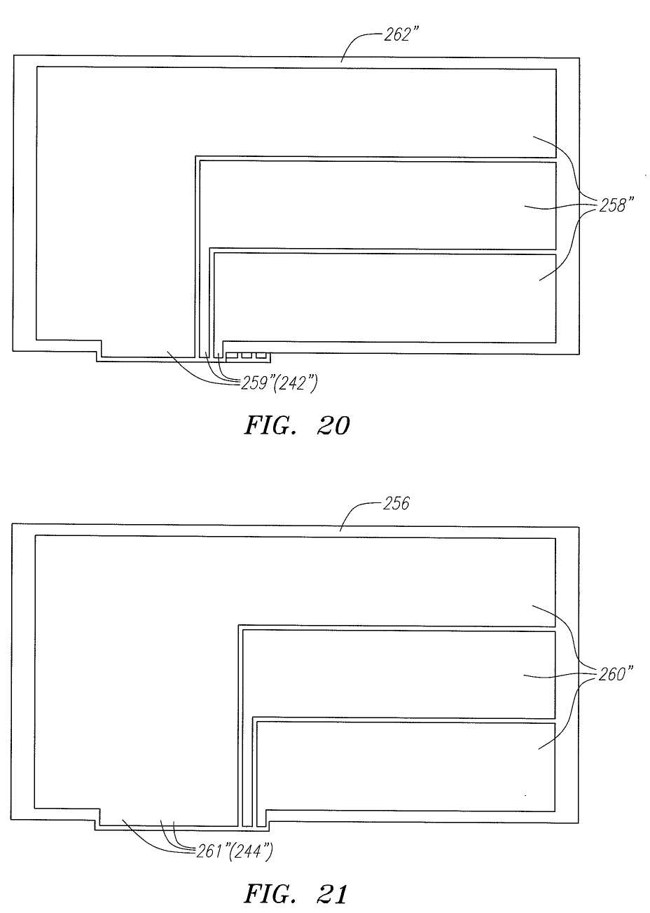

The layup of the piezoelectric package 222 can be created in the same manner as the creation of the piezoelectric package 122 described above, with the exception that, instead of a single upper piezoelectric plate and a single lower piezoelectric plate, the layup will accommodate three upper piezoelectric plates 224′ and three lower piezoelectric plates 224″. Notably, the set of electrically conductive sheets 258′ include tabs 259′ that form the first set of electrical contacts 242′ (FIG. 18), the set of electrically conductive sheets 260′ include tabs 261′ that form the second set of electrical contacts 244′ (FIG. 19), the set of electrically conductive sheets 258″ include tabs 259′ that form the third set of electrical contacts 242″ (FIG. 20), and the set of electrically conductive sheets 260″ include tabs 261″ that form the fourth set of electrical contacts 244″ (FIG. 21).

After the laminate structure has been laid-up, the movable sheet (not shown) with the laminate structure is placed into an oven and cured. During the curing process, the resin from the insulative sheets 254, 255, 256, 262′, 264′, 266′, 262″, 264″, 266″ flows to coat the fibers within these sheets and fill in any gaps within the structure that would otherwise form air pockets within the piezoelectric package 222. The resin then polymerizes into a rigid composite structure. As a result of this process, the outer insulative sheets 254, 256 form the outer structural material 240, the conductive sheets 258′, 260′, 258″, 260″ respectively form the electrically conductive layers 234′, 234″, 236′, 236″, the inner insulative sheets 255, 262′, 264′, 262″, 264″, as well as the thickening sheets 266′, 266″, form the inner structural material 238, and the electrically conductive sheets 268′, 270′, 268″, 270″ form the vertical conductors 246′, 248′, 246″, 248″, as shown in FIG. 16. Significantly, because the conductive sheets 258′, 260′, 258″, 260″ are porous, the resin from these sheets also flows into and polymerizes within the porous structure to strengthen the mechanical connection between the conductive sheets 258′, 260′, 258″, 260″ and insulative material.

The laminate structure of the piezoelectric package 222 can be vacuum sealed and cured in the same manner described above with respect to the laminate structure of the piezoelectric package 22. The connector assembly 125 (shown in FIGS. 9 and 10) can be connected to the contacts 242′, 244′, 242″, 244″ in the same manner discussed above with respect to the piezoelectric package 122. Solder or tape can be applied to the contacts 242′, 244′, 242″, 244″ prior to curing to prevent the resin from being disposed on the surfaces of the contacts 242′, 244′, 242″, 244″, or any excess resin on the surfaces of the contacts 242′, 244′, 242″, 244″ can be cleaned off with a tool, or the connector assembly 125 can be connected to the contacts 242′, 244′, 242″, 244″ prior to the curing process. Again, at various times between the lay-up of the laminate structure and the connection of the connector assembly 125 to the contacts 242′, 244′, 242″, 244″, the assembly can be electrically tested to ensure that the contacts 242′, 244′, 242″, 244″ are electrically independent from each other (via conductance measurements) and that the piezoelectric plates 224′, 224″ are properly working (via capacitance measurements).

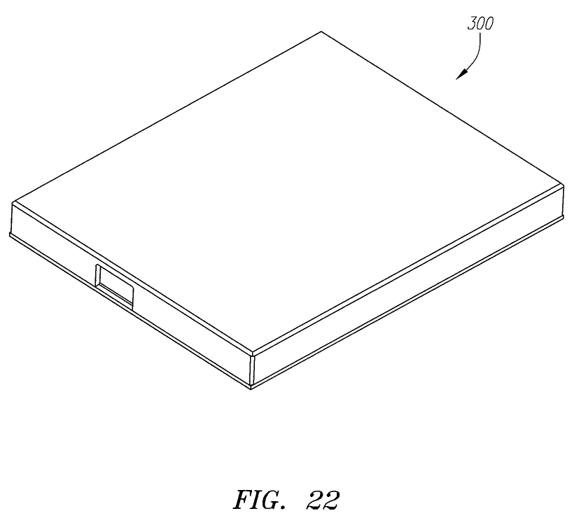

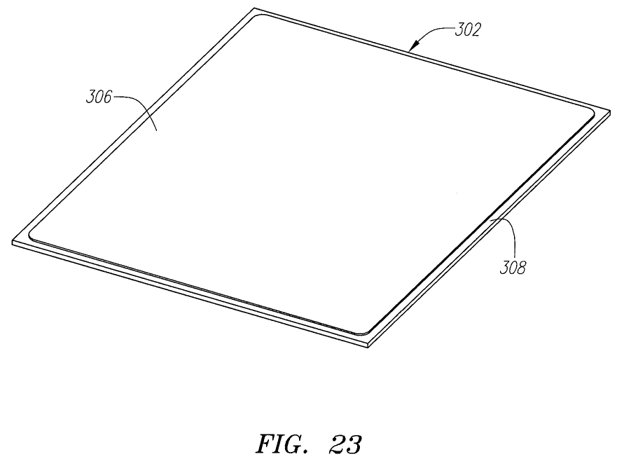

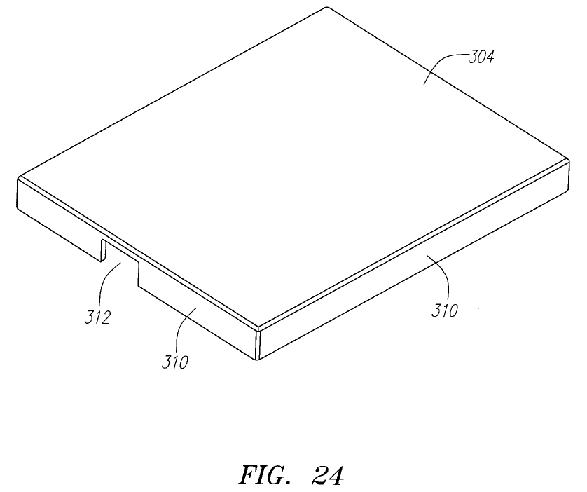

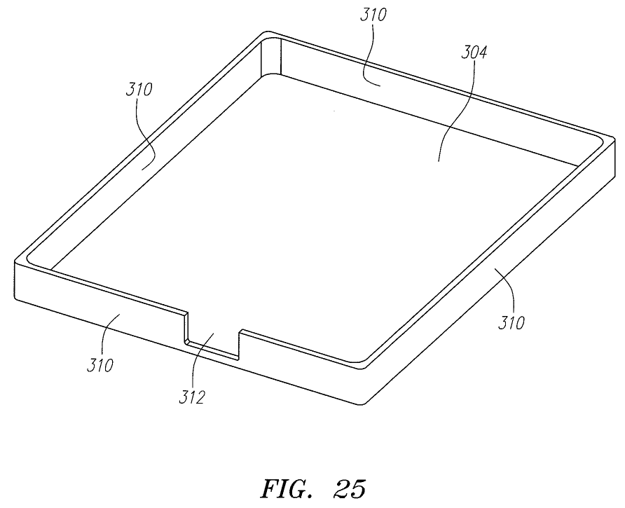

Referring now to FIGS. 22-25, any of the foregoing piezoelectric packages 22, 122, 222, can be incorporated into an environmental case 300 to create an environmentally protected piezoelectric package. The case 300 generally comprises a base plate 302 (FIG. 23) and a cover 304 (FIGS. 24 and 25), which may be composed of a suitable rigid material, such as, e.g., stainless steel. In the illustrated embodiment, the base plate 302 takes the form of a rectangular piece of sheet metal that includes a raised plane 306 on which the selected piezoelectric package can be disposed and a recess 308 around the raised plane 306. The base plate 302 is designed to be mounted to equipment via bonding.

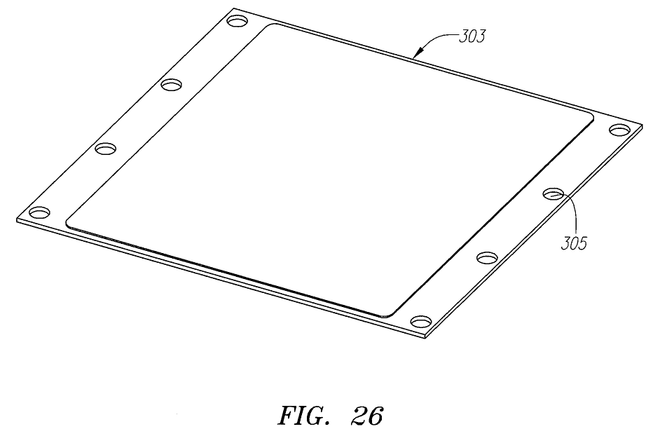

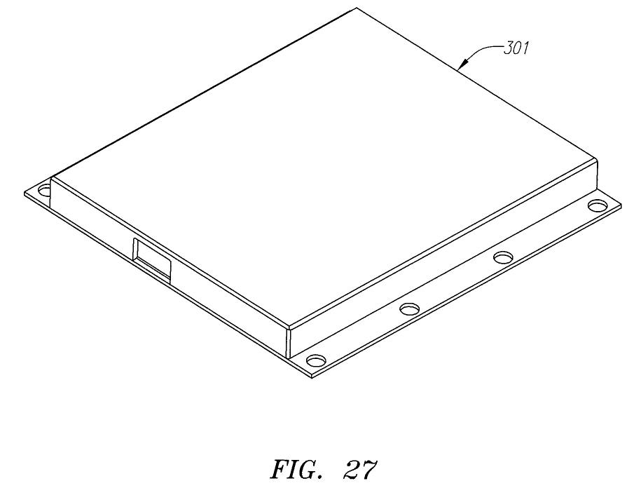

In an alternative embodiment, a base plate 303 (FIG. 26), which includes a plurality of holes 305 can be used with the cover 304 to create a case 301 (FIG. 27). In this case, the base plate 303 can be mounted to equipment using bolts (not shown) that can be screwed into the equipment through the holes 305.

As shown in FIGS. 24 and 25, the cover 304 takes the form of an open box having four walls 310 with edges that can fit within the recess 308 around the edges of the base plate 302. The cover 304 further includes an access opening 312 formed through one of the walls 310 to coincide with the connector 131 of the connector assembly 125 illustrated in FIGS. 9 and 10 when mounted within the case 300.

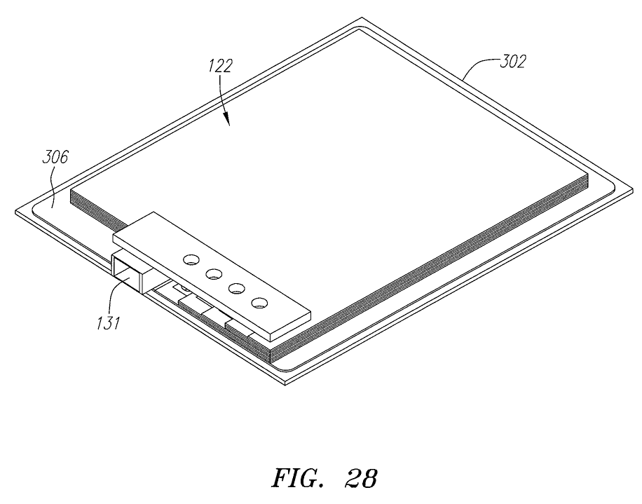

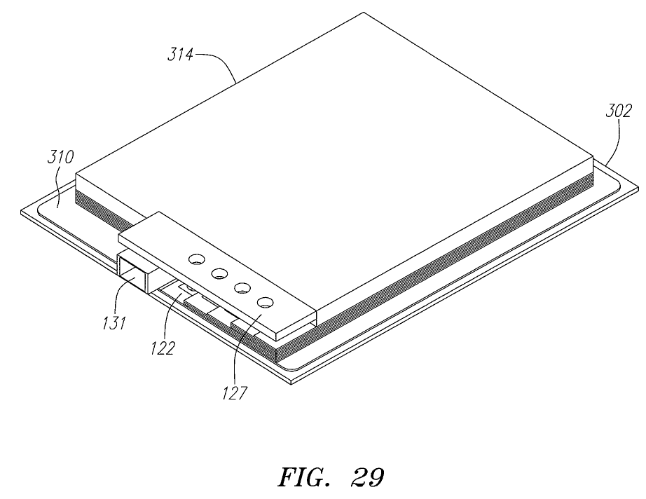

Having described the environmental case 300, the incorporation of a piezoelectric package (and in particular, the piezoelectric package 122) into the case 300, and the mounting of the case 300 onto equipment (not shown) will now be described with reference to FIGS. 28-31.

First, the piezoelectric package 122 and surfaces of the base plate 302 are cleaned with a suitable solvent, such as isopropyl alcohol. Next, as shown in FIG. 28, the piezoelectric package 122 is aligned with the raised plane 306 on the base plate 302 by using the connector 131 of the piezoelectric package 122 and the access opening 312 on the cover 304 (shown in FIGS. 23 and 24) as a guide. Next, the piezoelectric package 122 is mounted to the base plate 302 by bonding the bottom surface of the piezoelectric package 122 to the raised plane 306 using a suitable adhesive, such as, e.g., epoxy. During cure, pressure can be applied to the piezoelectric package 122 and base plate 302 using a clamp or a large weight. After cure, the capacitance of the piezoelectric plates (not shown) within the piezoelectric package 122 can be measured via the connector 131. The measured capacitance should be a small value relative to the capacitance previously measured before mounting the piezoelectric package 122 to the base plate 302.

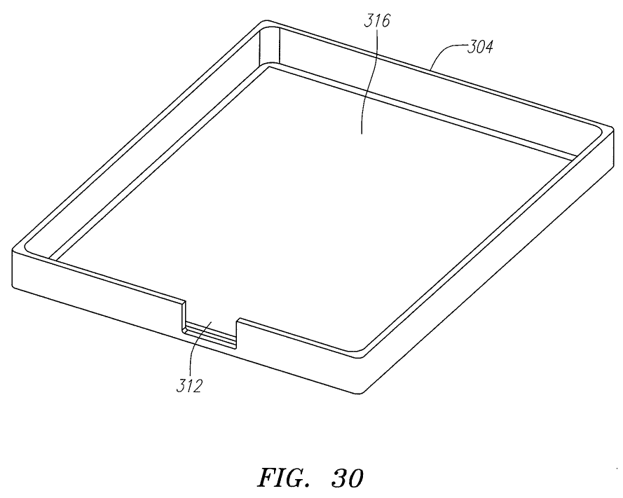

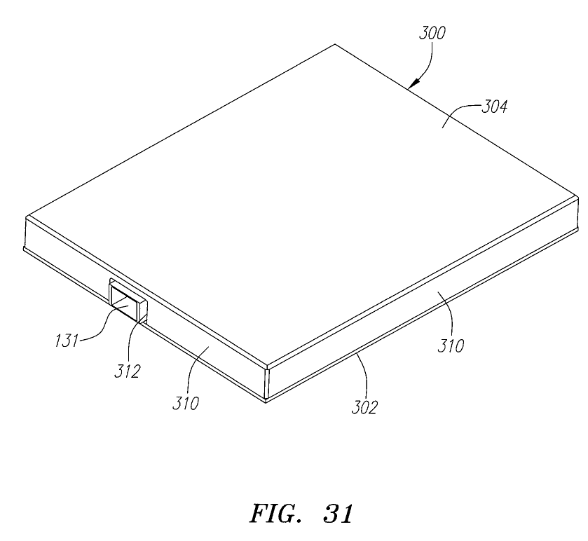

Next, as shown in FIG. 29, a rubber pad 314, which generally has the same shape and size as the composite structure of the piezoelectric package 122, is disposed over the piezoelectric package 122, thereby making the top of the piezoelectric package 122 uniform. The rubber pad 314 may be cut, so that it extends along the top of the composite of the piezoelectric package 122, while abutting the edge of the printed circuit board 127. In the alternative embodiment where the printed circuit board 127 extends along the entire top of the composite of the piezoelectric package 122, the rubber pad 314 may be located between the top of the composite and the bottom of the printed circuit board 127. Then, as shown in FIG. 30, the inside surface of the cover 304 is cleaned using a suitable solvent, such as, e.g., isopropyl alcohol, and a foam pad 316 is suitably bonded within the cover 304, thereby preventing any rattling of the piezoelectric package 122 within the case 300. Next, as shown in FIG. 31, the cover 304 is mounted to the base plate 302 by bonding the edges of the cover walls 310 within the recess 308 of the base plate 302 using a suitable adhesive, such as, e.g., epoxy. During cure, pressure can be applied to the base plate 302 and cover 304 using a clamp or a large weight. Alternatively, the cover 304 can be laser welded to the base plate 302. A bead of epoxy can be applied to the access opening 312 around the connector 131 to ensure that the case 300 is watertight. As shown in FIG. 31, the access opening 312 provides access to the connector 131, thereby allowing an external cable (not shown) to be conveniently connected to the piezoelectric package 122.

Although particular embodiments of the present invention have been shown and described, it should be understood that the above discussion is not intended to limit the present invention to these embodiments. It will be obvious to those skilled in the art that various changes and modifications may be made without departing from the spirit and scope of the present invention. Thus, the present invention is intended to cover alternatives, modifications, and equivalents that may fall within the spirit and scope of the present invention as defined by the claims.

What is claimed is:

1. A piezoelectric package, comprising:
a piezoelectric plate having first planar surface and a second planar surface that are electrically isolated from each other;
a first electrically conductive layer electrically coupled to the first planar surface, wherein a ratio of an area of the first electrically conductive layer to the area of the first planar surface is equal to or greater than unity;
a second electrically conductive layer electrically coupled to the second planar surface; and
a first electrically insulative material encapsulating the piezoelectric plate and at least portions of the first and second electrically conductive layers.

2. The piezoelectric package of claim 1, wherein a ratio of an area of the second electrically conductive layer to the area of the second planar surface is equal to or greater than unity.

3. The piezoelectric package of claim 1, wherein the first and second electrically conductive layers are composed of a porous material, and wherein a portion of the first electrically insulative material is embedded within the porous material.

4. The piezoelectric package of claim 3, wherein the porous material is mesh.

5. The piezoelectric package of claim 1, wherein the first electrically insulative material is composed of a rigid fiber composite material.

6. The piezoelectric package of claim 1, further comprising a second electrically insulative material disposed between the first and second electrically conductive layers.

7. The piezoelectric package of claim 6, wherein the second electrically insulative material is disposed over peripheral regions of the first planar surface and the second planar surface, the piezoelectric package further comprising:
a first vertical conductor electrically coupled between a center region of the first planar surface and the first electrically conductive layer; and
a second vertical conductor electrically coupled between a center region of the second planar surface and the second electrically conductive layer.

8. The piezoelectric package of claim 1, further comprising:
a first surface electrode covering the first planar surface, wherein the first electrically conductive layer is electrically coupled to the first planar surface via the first surface electrode; and
a second surface electrode covering the second planar surface, wherein the second electrically conductive layer is electrically coupled to the second planar surface via the second surface electrode.

9. The piezoelectric package of claim 1, further comprising:
a first electrical contact electrically coupled to the first electrically conductive layer; and
a second electrical contact electrically coupled to the second electrically conductive layer.

10. The piezoelectric package of claim 9, wherein the first electrically conductive layer has an exposed portion that forms the first electrical contact, and the second electrically conductive layer has an exposed portion that forms the second electrical contact.

11. The piezoelectric package of claim 9, further comprising a connector assembly coupled to the first and second electrical contacts.

12. The piezoelectric package of claim 11, wherein the connector assembly is configured for receiving an external cable.

13. The piezoelectric package of claim 1, further comprising another piezoelectric plate having a third planar surface and a fourth planar surface that are electrically isolated from each other, wherein the first electrically insulative material encapsulates the other piezoelectric plate.

14. The piezoelectric package of claim 13, wherein the first electrically conductive layer is electrically coupled to the third planar surface, and the second electrically conductive layer is electrically coupled to the fourth planar surface, and wherein a ratio of an area of the first electrically conductive layer to the total area of the first planar surface and third planar surface is equal to or greater than unity.

15. The piezoelectric package of claim 13, further comprising:
a third electrically conductive layer electrically coupled to the third planar surface, wherein a ratio of an area of the third electrically conductive layer to the area of the third planar surface is equal to or greater than unity;
a fourth electrically conductive layer electrically coupled to the fourth planar surface.

16. The piezoelectric package of claim 15, wherein a ratio of an area of the fourth electrically conductive layer to the area of the fourth planar surface is equal to or greater than unity.

17. The piezoelectric package of claim 15, wherein the piezoelectric plate and the other piezoelectric plate extend in a same plane.

18. The piezoelectric package of claim 15, wherein the piezoelectric plate and the other piezoelectric plate extend in different planes.

19. The piezoelectric package of claim 1, further comprising a case containing the piezoelectric plate, the first and second electrically conductive layers, and the first electrically insulative material.

20. A system, comprising:
equipment susceptible to vibration;
the piezoelectric package of claim 1 mounted on the equipment; and
electronic circuitry electrically coupled to the piezoelectric package, the electronic circuitry configured for sensing and/or actuating vibrations within the equipment via the piezoelectric package.
